(19) United States
(12) Patent Application Publication
(10) Pub. No.: US 2025/0008722 A1
(43) Pub. Date: Jan. 2, 2025

(54) METHOD OF FORMING PATTERNS AND METHOD OF MANUFACTURING A SEMICONDUCTOR DEVICE USING THE SAME

(71) Applicant: SAMSUNG ELECTRONICS CO., LTD., Suwon-si (KR)

(72) Inventors: Gyeyoung KIM, Suwon-si (KR); Sangho Yun, Suwon-si (KR); Jeonghee Choi, Suwon-si (KR); Woojin Jung, Suwon-si (KR)

(73) Assignee: SAMSUNG ELECTRONICS CO., LTD., Suwon-si (KR)

(21) Appl. No.: 18/631,884

(22) Filed: Apr. 10, 2024

(30) Foreign Application Priority Data
Jun. 30, 2023 (KR) 10-2023-0085257

(51) Int. Cl. H10B 12/00; H01L 21/308; H01L 21/762

(52) U.S. Cl. CPC H10B 12/053; H01L 21/3086; H01L 21/76224; H10B 12/0335

(57) ABSTRACT

A method of forming a pattern is provided. The method includes: forming a first recess in a substrate; forming a first mask layer on the substrate that extends into the first recess; performing a heat treatment process on the first mask layer; removing an upper portion of the first mask layer to form a first mask in the first recess, the first mask comprising a lower portion of the first mask layer; forming a second mask on the substrate and the first mask, the second mask comprising a material having a tolerance with respect to an etching process that is greater than that of the first mask; and performing an etching process on the substrate using the second mask as an etching mask to form the pattern on the substrate.

### CROSS-REFERENCE TO RELATED APPLICATION

This application claims priority to Korean Patent Application No. 10-2023-0085257, filed on Jun. 30, 2023, in the Korean Intellectual Property Office, the disclosure of which is incorporated by reference herein in its entirety.

### BACKGROUND

### 1. Field

The present disclosure relates to a method of forming a pattern and a method of manufacturing a semiconductor device using the same. More particularly, the present disclosure relates to a method of forming a pattern and a method of manufacturing a dynamic random-access memory (DRAM) device using the same.

### 2. Related Art

In a method of manufacturing a semiconductor device, a mask layer may be formed on an object layer, a photoresist layer may be formed on the mask layer, a photo process may be performed on the photoresist layer to transform the photoresist layer into a photoresist pattern, an etching process may be performed on the mask layer using the photoresist pattern as an etching mask to transform the mask layer into a mask, and an etching process may be performed on the object layer using the mask as an etching mask to form a pattern in the object layer.

If an upper surface of the object layer does not have a uniform height, when the photo process is performed on the photoresist layer, a defocusing phenomenon may occur, and cause the photoresist pattern to not have a desired shape.

### SUMMARY

One or more example embodiments provide a method of forming a pattern having improved characteristics.

One or more example embodiments provide a method of manufacturing a semiconductor device having improved characteristics.

According to example embodiments, a method of forming a pattern includes: forming a first recess in a substrate; forming a first mask layer on the substrate that extends into the first recess; performing a heat treatment process on the first mask layer; removing an upper portion of the first mask layer to form a first mask in the first recess, the first mask comprising a lower portion of the first mask layer; forming a second mask on the substrate and the first mask, the second mask comprising a material having a tolerance with respect to an etching process that is greater than that of the first mask; and performing an etching process on the substrate using the second mask as an etching mask to form the pattern on the substrate.

According to example embodiments, a method of forming a pattern includes: forming a recess in a substrate; forming a first mask layer on the substrate that extends into the recess, wherein an upper surface of the first mask layer is closer to the substrate on a portion of the substrate having the recess thereon than on a portion of the substrate spaced apart from the recess; removing an upper portion of the first mask layer to form a first mask in the recess, the first mask comprising a portion of the first mask layer; forming a second mask on the substrate and the first mask, the second mask comprising a material different from that of the first mask, and an upper surface of the second mask having a uniform height with respect to the substrate; and performing an etching process on the substrate using the second mask as an etching mask to form the pattern on the substrate.

According to example embodiments, a method of manufacturing a semiconductor device includes: forming a first recess in a first region of a substrate, the substrate comprising the first region and a second region; forming a first mask layer on the substrate that extends into the first recess; performing a heat treatment process on the first mask layer; removing an upper portion of the first mask layer to form a first mask in the first recess, the first mask comprising a portion of the first mask layer; forming a second mask on the substrate and the first mask, the second mask comprising a material having a tolerance with respect to an etching process that is greater than that of the first mask; performing an etching process using the second mask as an etching mask on the substrate and the first mask to form second and third recesses in the first and second regions, respectively, of the substrate, a first active pattern being defined by the first and second recesses on the first region of the substrate and a second active pattern being defined by the third recess on the second region of the substrate; forming an isolation structure in the first to third recesses; forming a gate structure through the first active pattern and the isolation structure in the first region of the substrate; forming a bit line structure on a portion of the first active pattern and a portion of the isolation structure; forming a contact plug structure on the portion of the first active pattern; and forming a capacitor on the contact plug structure.

According to example embodiments, a semiconductor device includes: a substrate defining a first recess; a first mask provided in the first recess that comprises spin-on-hardmask (SOH) that has undergone a heat treatment; and a second mask provided on active patterns of the substrate adjacent the first mask. An upper surface of the first mask is coplanar with an upper surface of the second mask.

### BRIEF DESCRIPTION OF DRAWINGS

The above and other objects, features and advantages will be more apparent from the following description of example embodiments, taken in conjunction with the accompanying drawings, in which:

FIGS. 1 to 12 are plan views and cross-sectional views illustrating a method of forming a pattern in accordance with example embodiments; and

FIGS. 13 to 51 are plan views and cross-sectional views illustrating a method of manufacturing a semiconductor device in accordance with example embodiments.

### DETAILED DESCRIPTION

The above and other aspects and features of a semiconductor device and a method of forming the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the present disclosure. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation.

Hereinafter, two directions among horizontal directions that are substantially parallel to an upper surface of a substrate may be referred to as first and second directions D1 and D2, respectively, and a direction among the horizontal directions, which has acute angle with respect to the first and second directions D1 and D2, may be referred to as a third direction D3. A direction substantially perpendicular to the upper surface of the substrate may be referred to as a vertical direction.

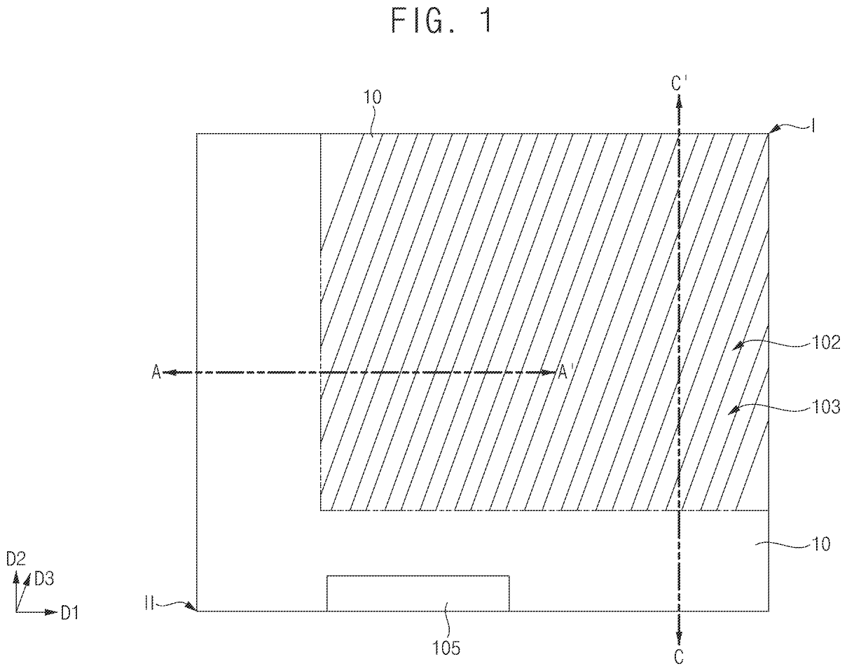

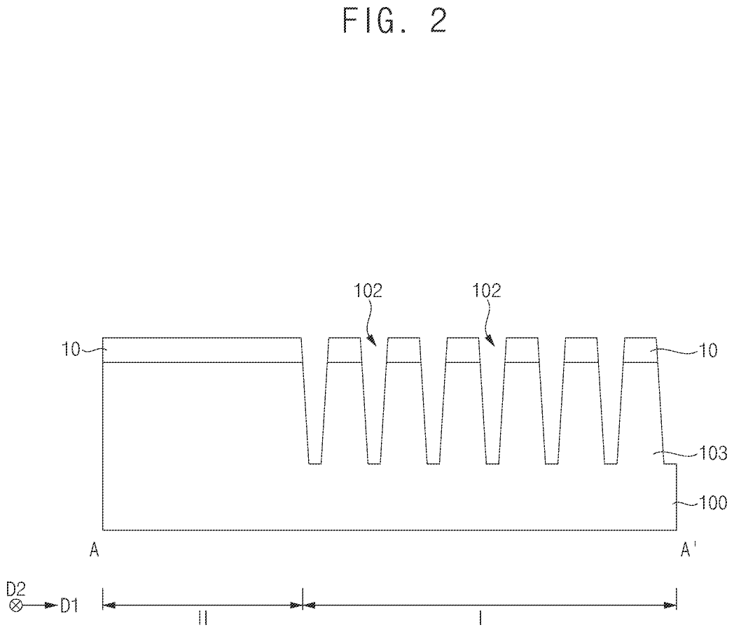

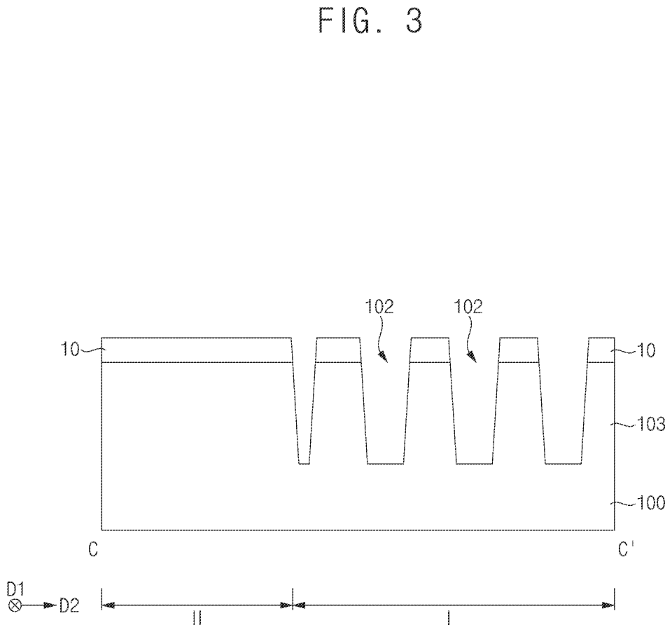

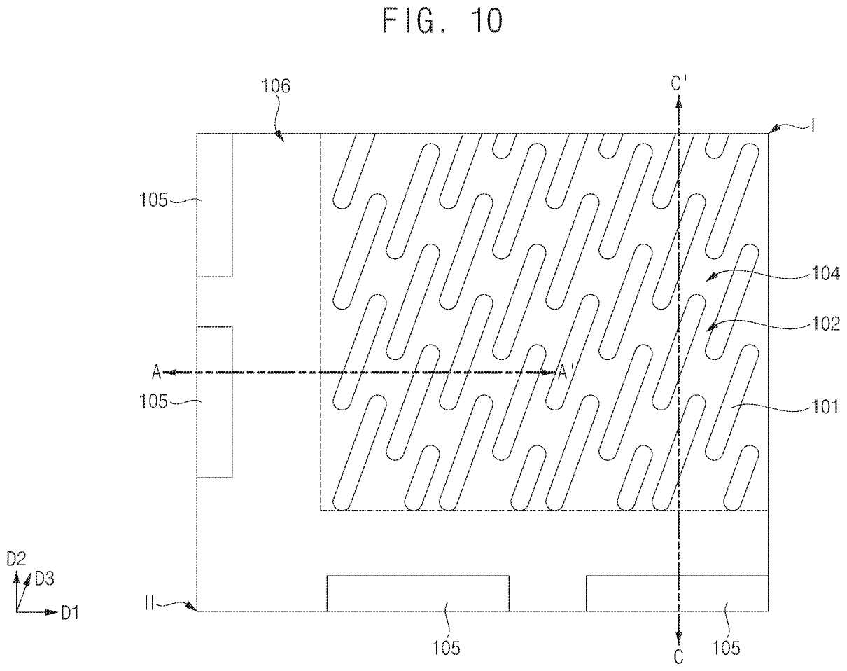

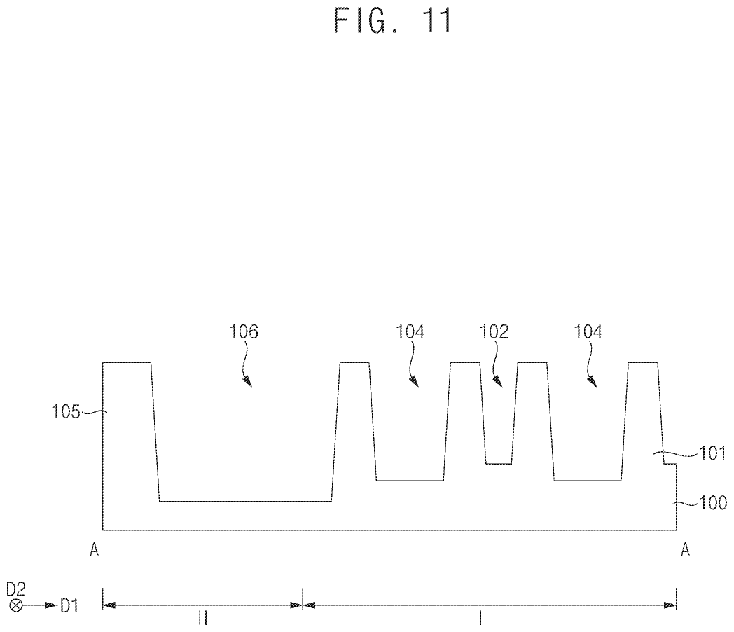

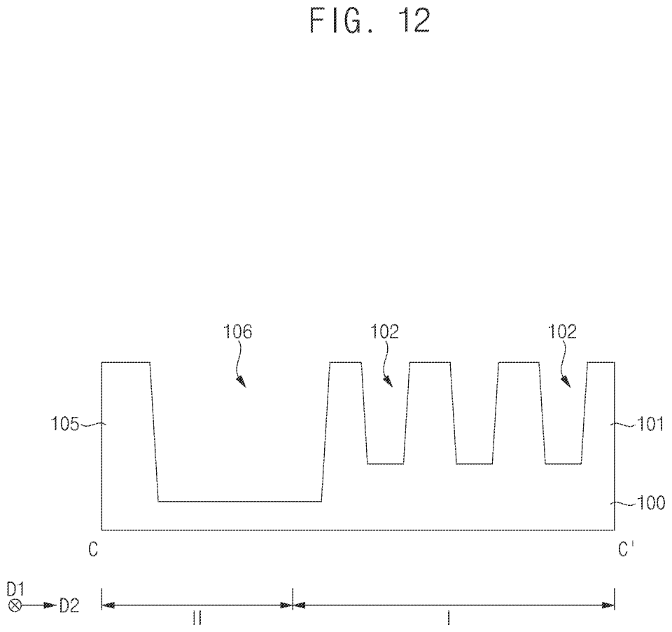

FIGS. 1 to 12 are plan views and cross-sectional views illustrating a method of forming a pattern in accordance with example embodiments. Particularly, FIGS. 1 and 10 are the plan views, FIGS. 2, 8 and 11 are cross-sectional views taken along lines A-A′ of corresponding plan views, respectively, and FIGS. 3-7, 9 and 12 are cross-sectional views taken along lines C-C′ of corresponding plan views, respectively.

Referring to FIGS. 1 to 3, a first mask 10 may be formed on a substrate 100, and an etching process may be performed using the first mask 10 as an etching mask to remove an upper portion of the substrate 100, to form a plurality of first recesses 102.

The substrate 100 may include silicon, germanium, silicon-germanium, or a III-V group compound semiconductor, such as GaP, GaAs, or GaSb. In example embodiments, the substrate 100 may be a silicon-on-insulator (SOI) substrate or a germanium-on-insulator (GOI) substrate.

The substrate 100 may include a first region I and a second region II. In an example embodiment, the first region I of the substrate 100 may be a cell region in which memory cells are formed, and the second region II of the substrate 100, which may surround the first region I, may be a peripheral circuit region in which peripheral circuit patterns for driving the memory cells are formed. However, example embodiments are not limited thereto. A portion of the first region I of the substrate 100, and a portion of the second region II adjacent to the first region I of the substrate 100 are shown in the drawings.

In an example embodiment, a plurality of first recesses 102 may be spaced apart from each other in the first direction D1 on the first region I of the substrate 100, and each of the plurality of first recesses 102 may extend in the third direction D3. As the plurality of first recesses 102 are formed, a preliminary first active pattern 103 may be formed on the first region I of the substrate 100.

In an example embodiment, the first mask 10 may include an oxide, e.g., silicon oxide.

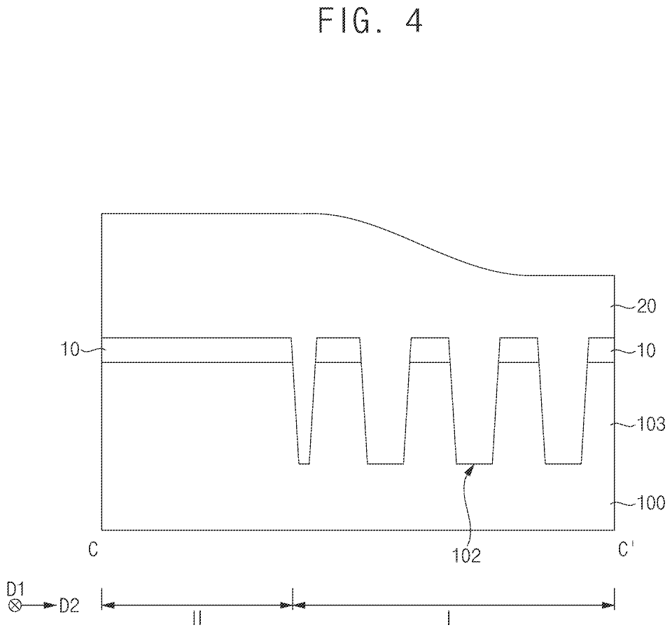

Referring to FIG. 4, a second mask layer 20, which may have an upper surface higher than an upper surface of the first mask 10, may be formed on the first and second regions I and II of the substrate 100 on which the preliminary first active pattern 103 and the first mask 10 are formed. The second mask layer 20 may fill the plurality of first recesses 102.

In example embodiments, the second mask layer 20 may include, e.g., spin-on-hardmask (SOH), and may be formed by a spin coating process. Thus, the second mask layer 20 may fill the plurality of first recesses 102 on the first region I of the substrate 100, and a height of an upper surface of a portion of the second mask layer 20 on the first region I of the substrate 100 may be lower than a height of an upper surface of a portion of the second mask layer 20 on the second region II of the substrate 100.

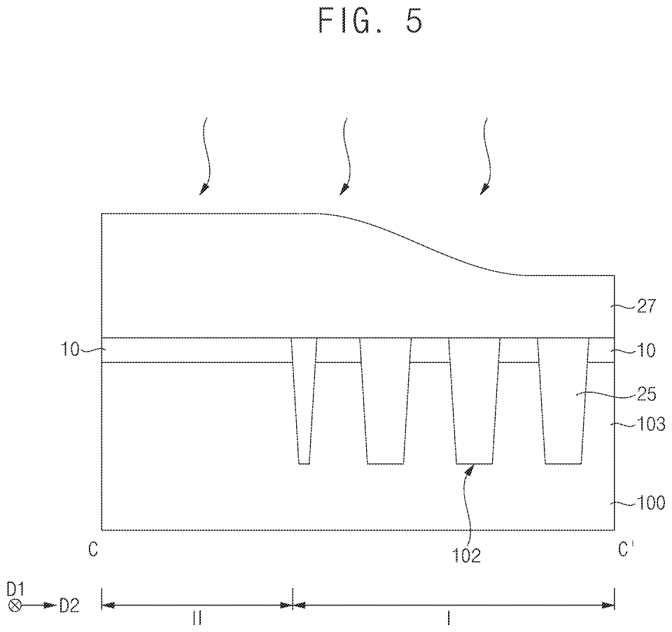

Referring to FIG. 5, a heat treatment process, e.g., a baking process may be performed on the second mask layer 20.

In an example embodiment, the heat treatment process may be performed at a temperature of about 145° C. to about 155° C. for about 60 seconds to about 150 seconds. As the heat treatment process is performed, a portion of the second mask layer 20 in the plurality of first recesses 102 may be partially cured and thereby converted into a second mask 25, and a portion of the second mask layer 20 on the first mask 10 and over the plurality of first recesses 102 may be transformed into a sacrificial mask 27.

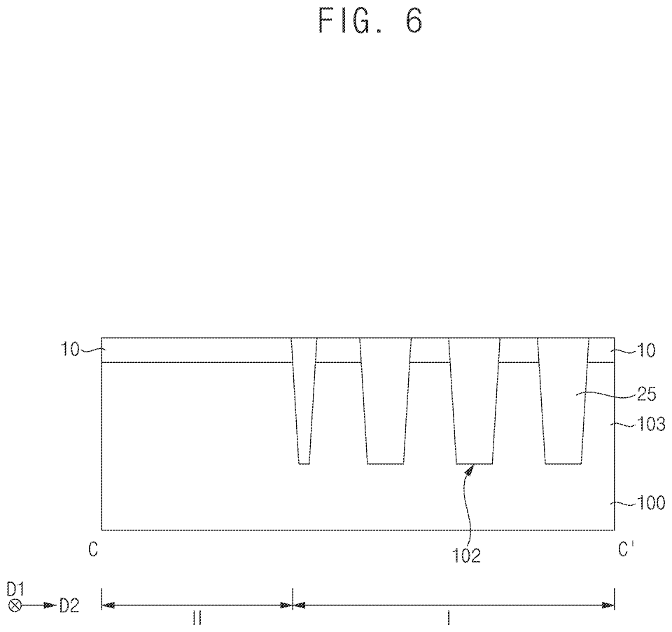

Referring to FIG. 6, an etching process, e.g., a rinse process using organic solvent, may be performed to remove the sacrificial mask 27.

After removing the sacrificial mask 27, an upper surface of the remaining second mask 25 may be substantially coplanar with an upper surface of the first mask 10. That is, the upper surfaces of the first and second masks 10 and 25 on the substrate 100 may have a uniform height.

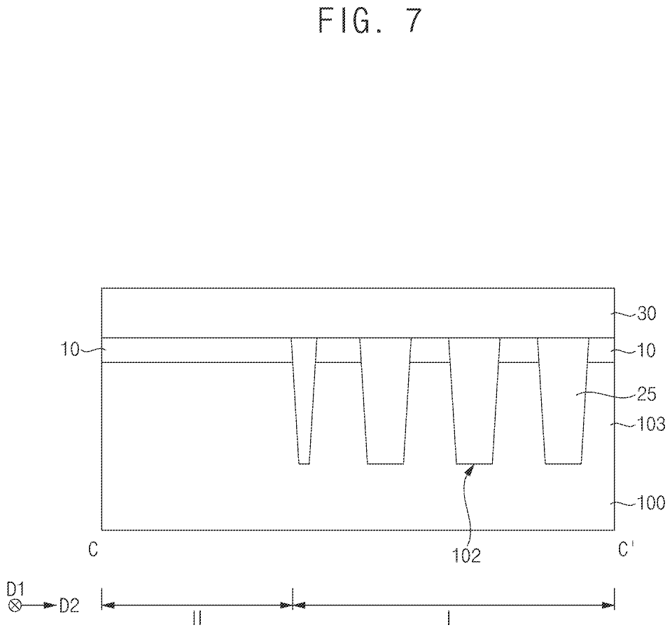

Referring to FIG. 7, a third mask layer 30 may be formed on the first and second masks 10 and 25.

In example embodiments, the third mask layer 30 may include a material having a tolerance with respect to an etching process higher than that of the second mask 25, e.g., amorphous carbon layer (ACL), and may be formed by a deposition process, e.g., a chemical vapor deposition (CVD) process.

The third mask layer 30 may be formed on the upper surfaces of the first and second masks 10 and 25 having a uniform height, and thus an upper surface of the third mask layer 30 may also have a uniform height.

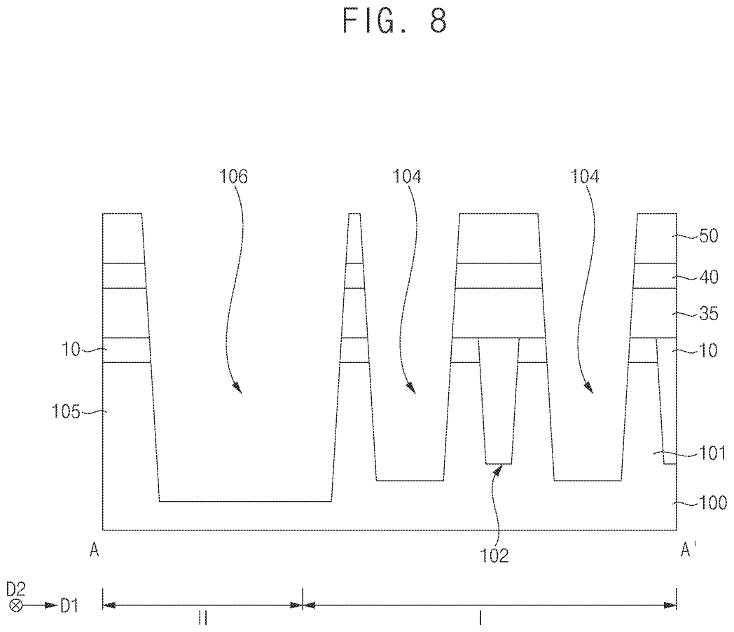

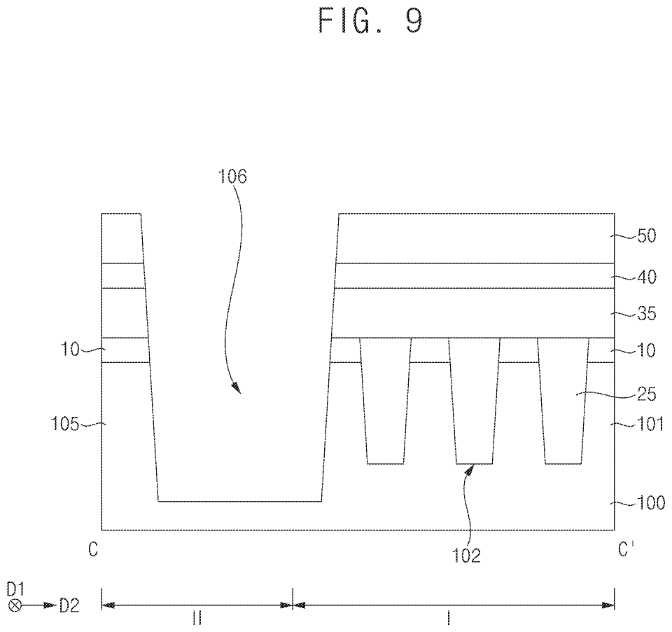

Referring to FIGS. 8 and 9, a fourth mask layer may be formed on the third mask layer 30, and a fifth mask layer may be formed on the fourth mask layer.

In an example embodiment, the fourth mask layer may include silicon oxynitride, and the fifth mask layer may be a photoresist layer.

A photo process, that is, an exposure process and a development process, may be performed on the fifth mask layer to form a fifth mask 50, and the fourth mask layer may be patterned using the fifth mask 50 as an etching mask to form a fourth mask 40.

During the etching process, a portion of the fifth mask 50 may be removed, and a remaining portion of the fifth mask 50 may be removed by, e.g., an ashing process and/or a stripping process.

The third mask layer 30 may be patterned using the fourth mask 40 as an etching mask to form a third mask 35. During the etching process, a portion of the fourth mask 40 may be removed.

The first and second masks 10 and 25, the preliminary first active pattern 103, and an upper portion of the second region II of the substrate 100 may be etched by an etching process using the third mask 35 as an etching mask.

As the etching process is performed, the preliminary first active pattern 103 between the first recesses 102 and an upper portion of the first region I of the substrate 100 thereunder may be partially removed to form a second recess 104 on the first region I of the substrate 100, and thus the preliminary first active pattern 103 may be divided into a plurality of first active patterns 101 spaced apart from each other in the third direction D3.

Additionally, as the etching process is performed, an upper portion of the second region II of the substrate 100 may be removed to form a third recess 106, and a second active pattern 105 surrounded by the third recess 106 may be formed.

In example embodiments, a width and a depth of the second recess 104 may be greater than a width and a depth, respectively, of a first recess 102, and a width and a depth of the third recess 106 may be greater than a width and a depth, respectively, of the second recess 104.

During the etching process, the remaining fourth mask 40 may be removed, and at least a portion of the third mask 35 may be entirely removed. For example, at least a lower portion of the third mask 35 may remain.

Referring to FIGS. 10 to 12, the first to third masks 10, 25 and 35 may be removed.

Each of the second and third masks 25 and 35 may be removed by, e.g., an ashing process and/or a stripping process, and the first mask 10 may be removed by, e.g., a wet etching process or a dry etching process.

By the above processes, the first and second active patterns 101 and 105 may be formed on the first and second regions I and II, respectively, of the substrate 100.

As described above, when the first recesses 102 are formed on the first region I of the substrate 100, and the second mask layer 20 is formed on the first and second regions I and II of the substrate 100 to fill the first recesses 102, the upper surface of the portion of the second mask layer 20 on the second region II of the substrate 100 may be higher than the upper surface of the portion of the second mask layer 20 on the first region I of the substrate 100.

Thus, if the fourth and fifth mask layers are directly formed on the second mask layer 20 and an exposure process is performed on the fifth mask layer, the upper surface of the fifth mask layer does not have a uniform height, and thus, during the exposure process, the focus of the light may not be aligned between the first and second regions I and Il of the substrate 100 such that the fifth mask 50 may not have a desired shape.

Additionally, after patterning the fourth mask layer to form a fourth mask, when the second mask layer 20 is patterned by an etching process using the fourth mask as an etching mask to form a second mask, the second mask layer 20 does not have a uniform thickness, and thus the second mask may not be well formed at a boundary between the first and second regions I and II of the substrate 100. Accordingly, when the first mask 10 and an upper portion of the substrate 100 are etched by an etching process using the second mask as an etching mask, an upper portion of the second region II of the substrate 100 and an upper portion of the boundary between the first and second regions I and II of the substrate 100 may not be properly removed, and as a result, the first and second active patterns 101 and 105 may not have desired shapes and layouts on the first and second regions I and II, respectively, of the substrate 100.

However, in example embodiments, a heat treatment process may be performed on the second mask layer 20 to convert a lower portion and an upper portion of the second mask layer 20 into the second mask 25 and the sacrificial mask 27, respectively, the sacrificial mask 27 may be removed by an etching process, and the third mask layer 30 may be formed on the first and second masks 10 and 25 by a deposition process. As the upper surfaces of the first and second masks 10 and 25 have the uniform height, the third mask layer 30 may have a uniform thickness, and each of the fourth mask layer and the fifth mask layer that may be formed on the third mask layer 30 may also have a uniform thickness.

Accordingly, during the exposure process on the fifth mask layer, the defocusing phenomenon between the first and second regions I and II of the substrate 100 may be prevented, and during the etching process using the third mask 35 as an etching mask, the upper portion of the second region II of the substrate 100 and the upper portion of the boundary between the first and second regions I and II of the substrate 100 may be easily removed.

The third mask 35 on the first and second masks 10 and 25 may include, e.g., ACL, which may have a tolerance with respect to an etching process higher than that of SOH included in the second mask 25. Thus, even though the third recess 106 is formed to have a relatively large depth by an etching process using the third mask 35 as an etching mask, the third mask 35 may not be entirely removed by the etching process, and at least a lower portion of the third mask 35 may remain. Accordingly, the third recess 106 and the second active pattern 105 may be formed to have desired widths, depths and/or shapes.

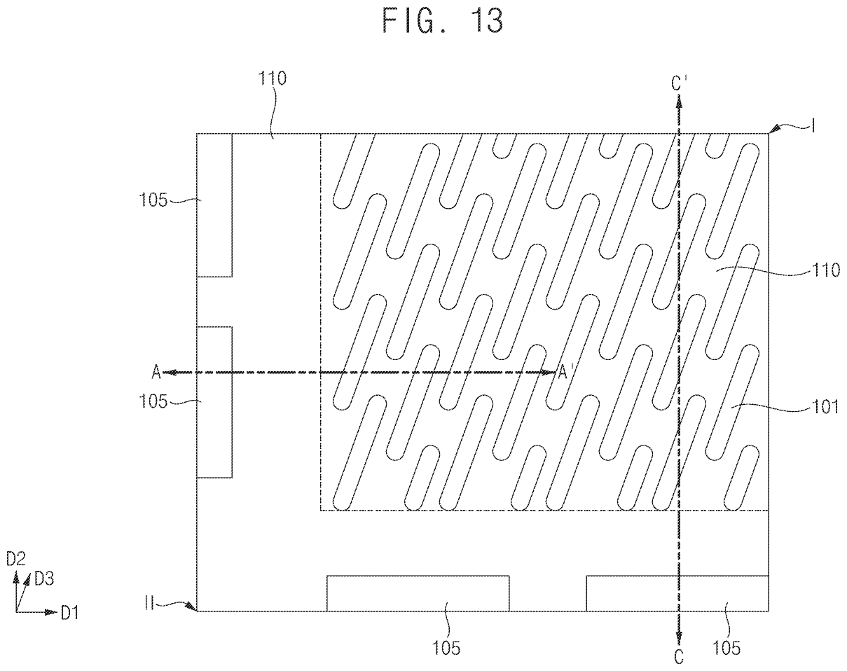

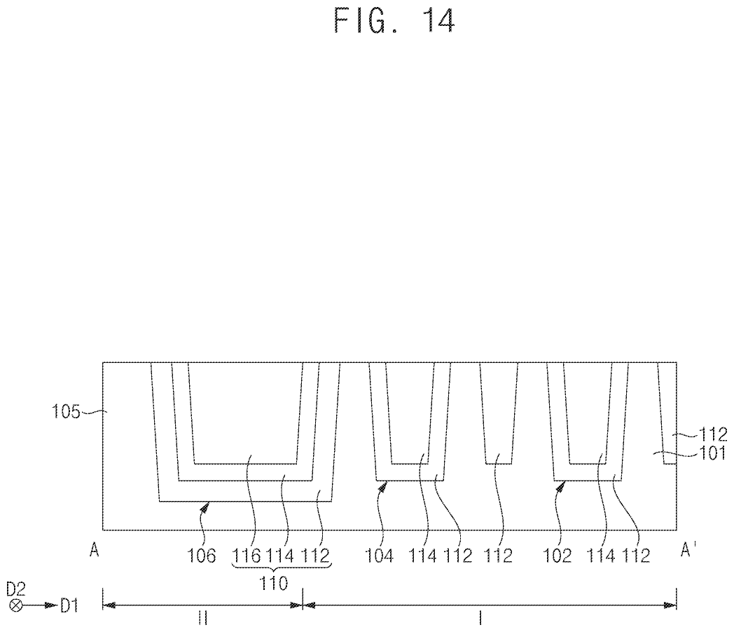

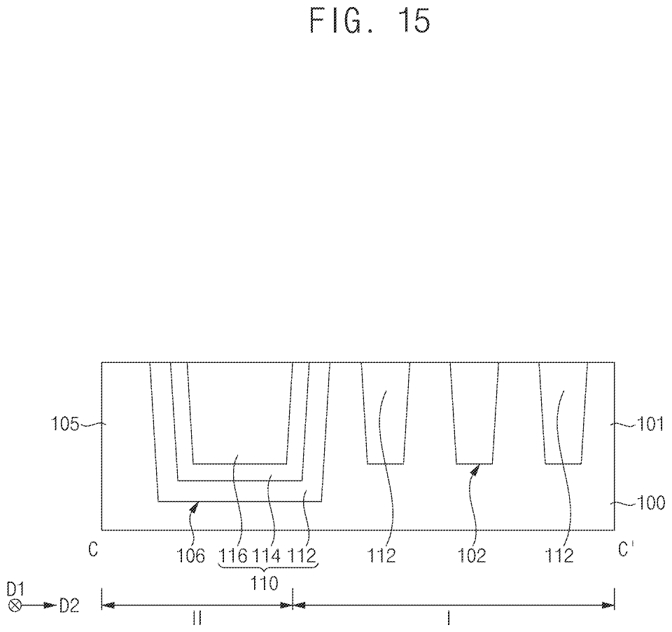

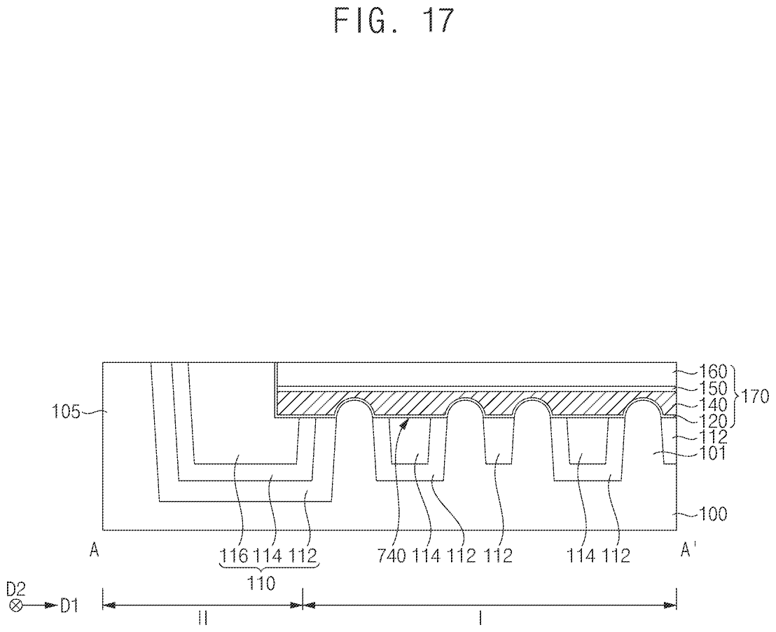

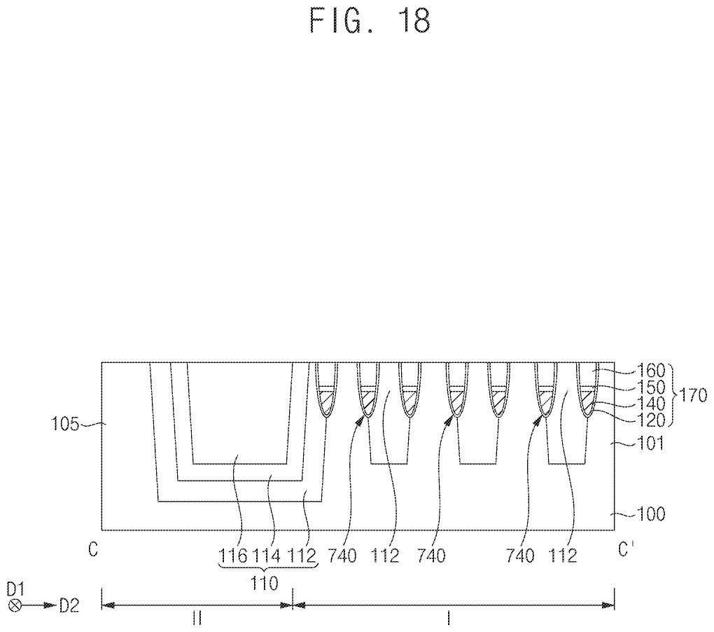

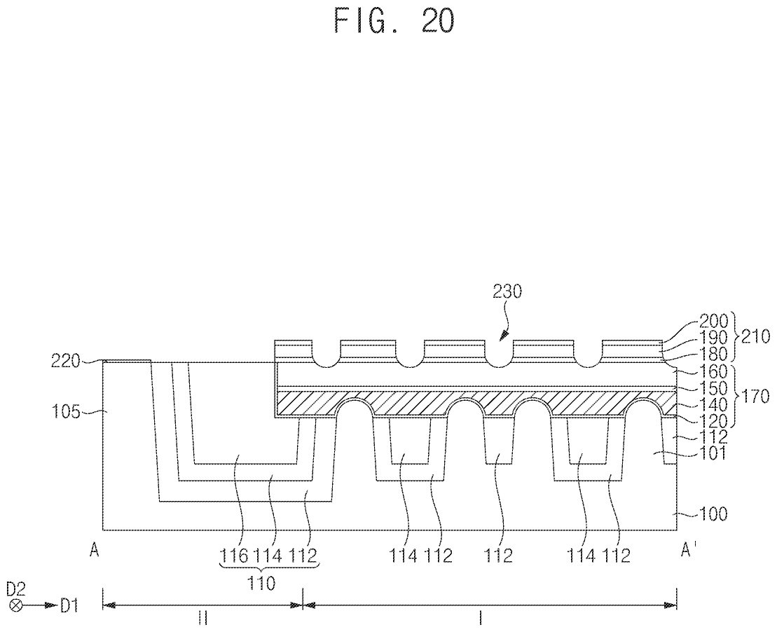

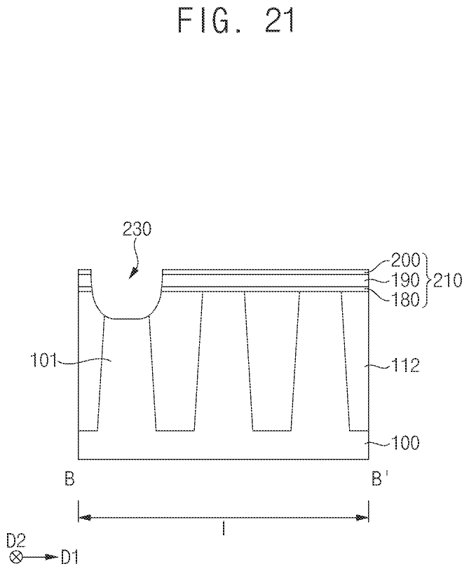

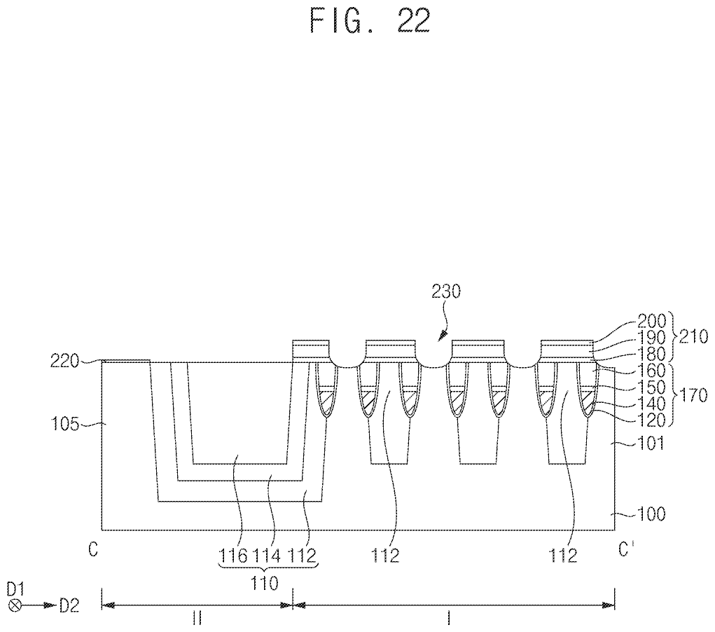

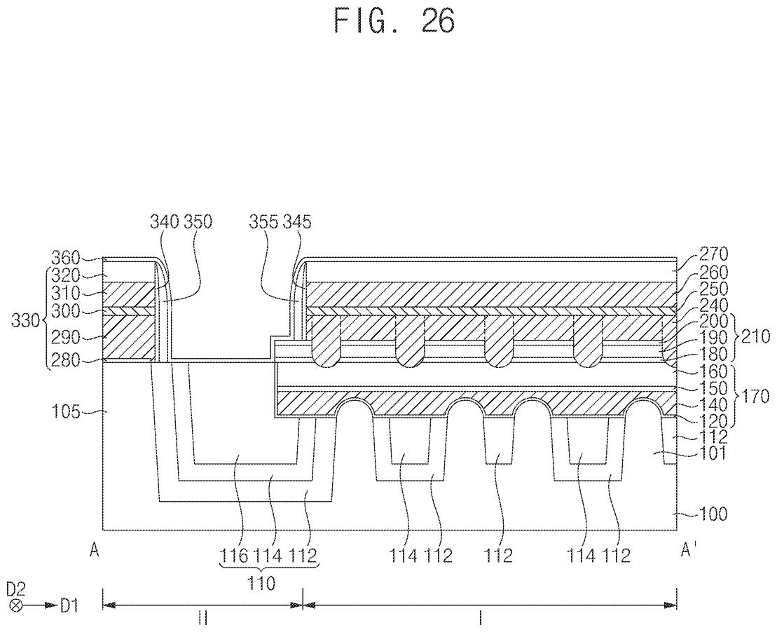

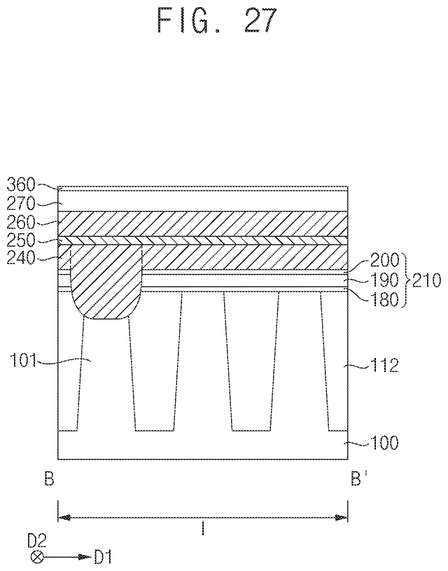

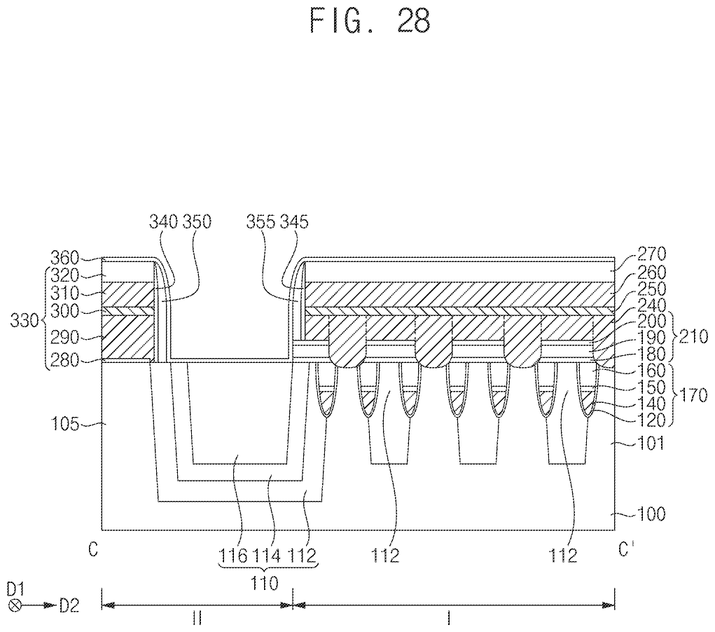

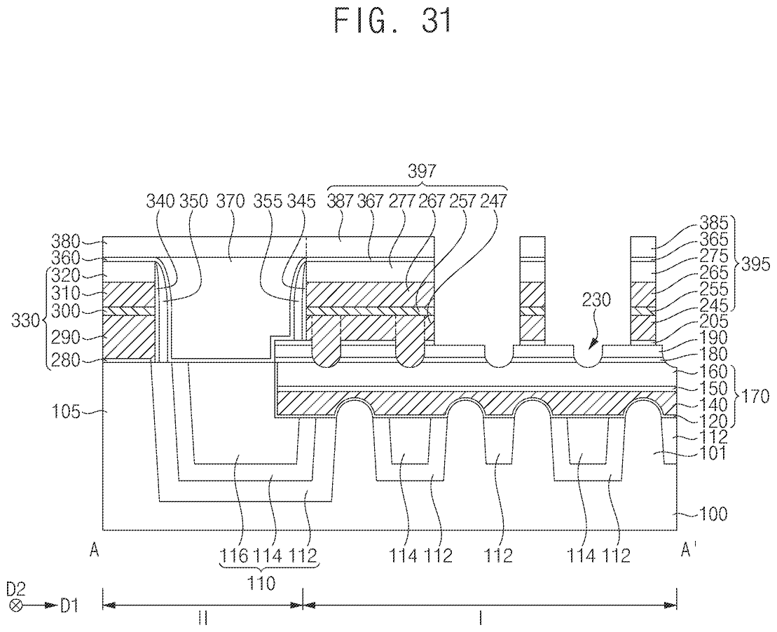

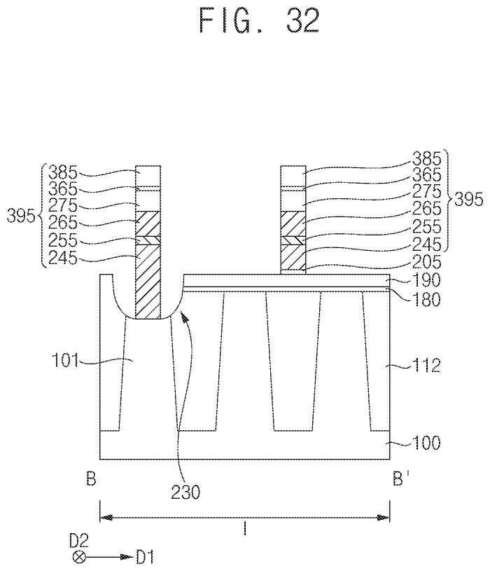

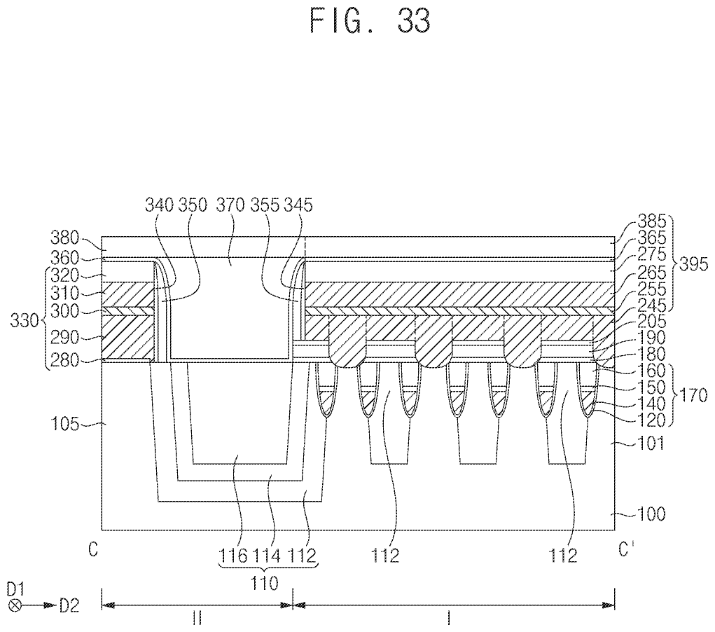

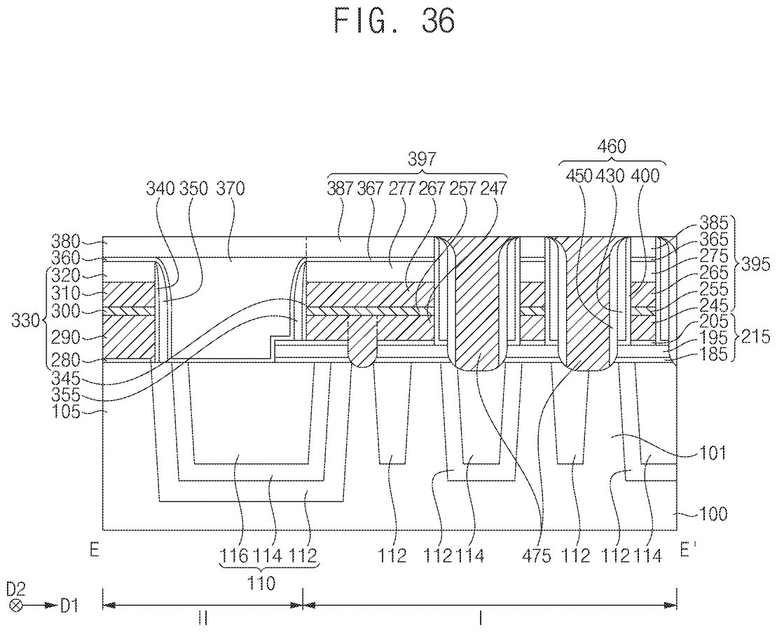

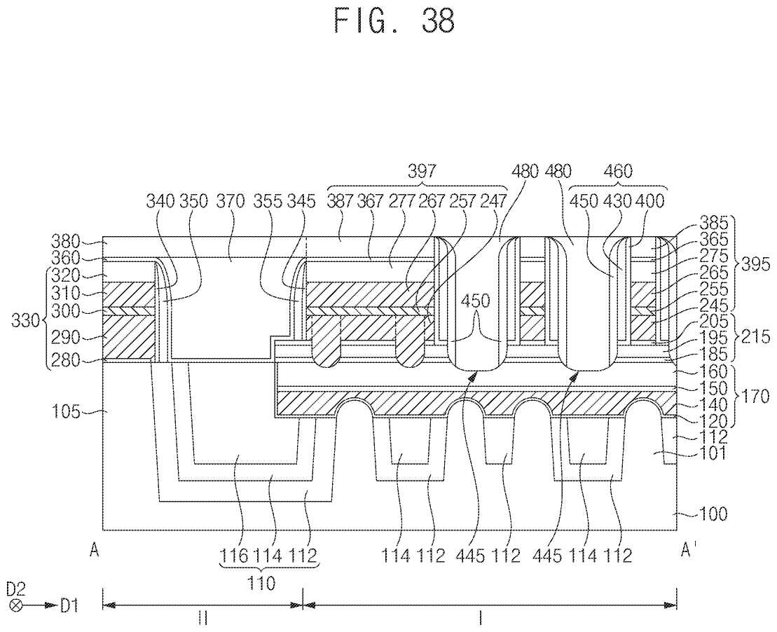

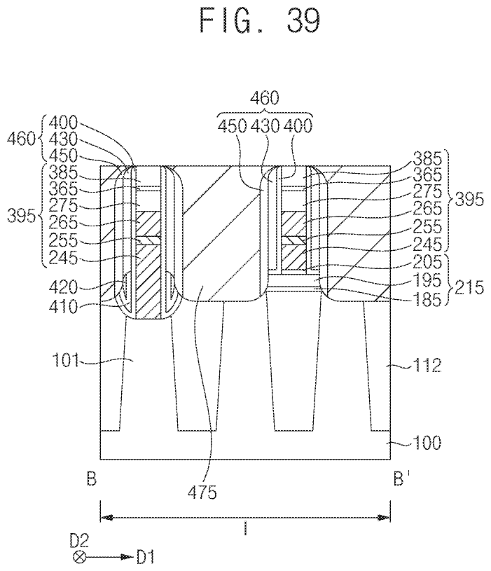

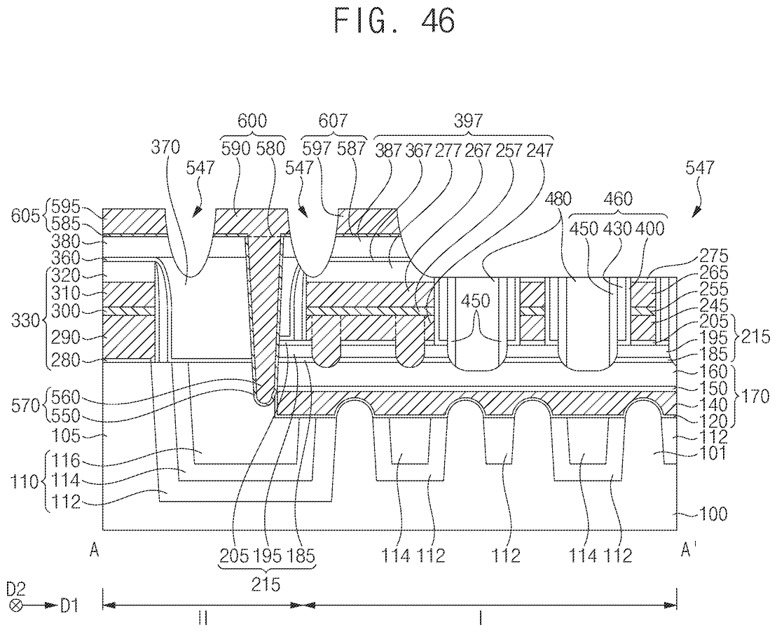

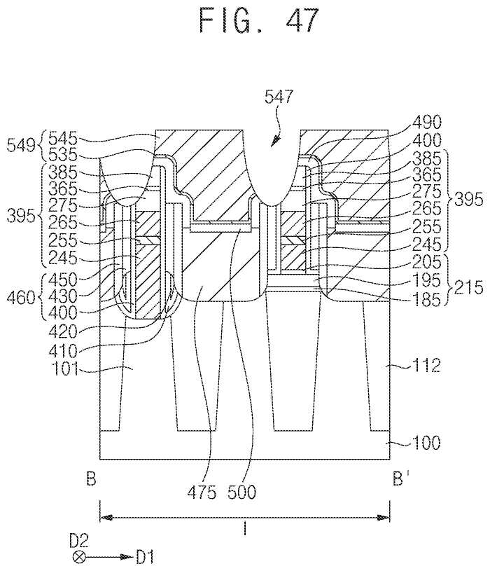

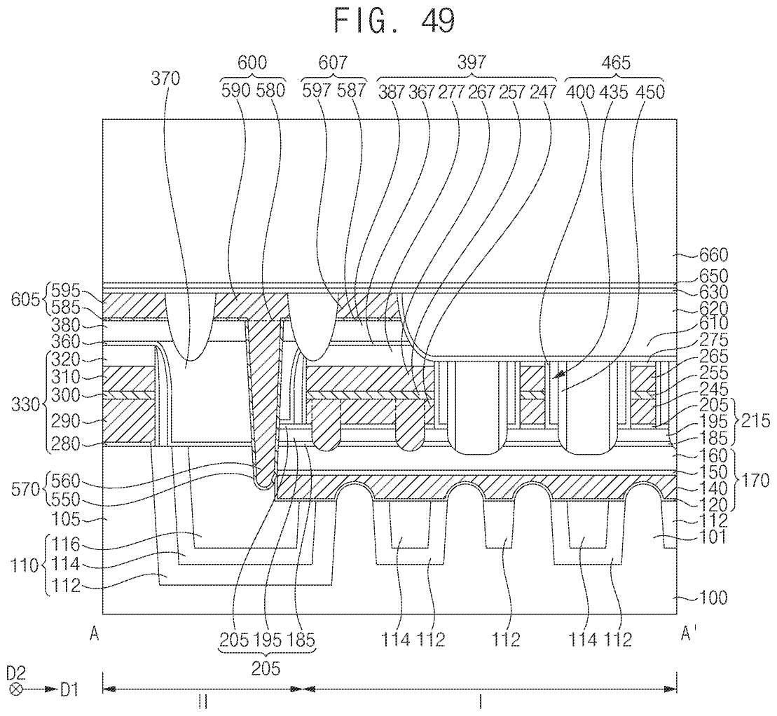

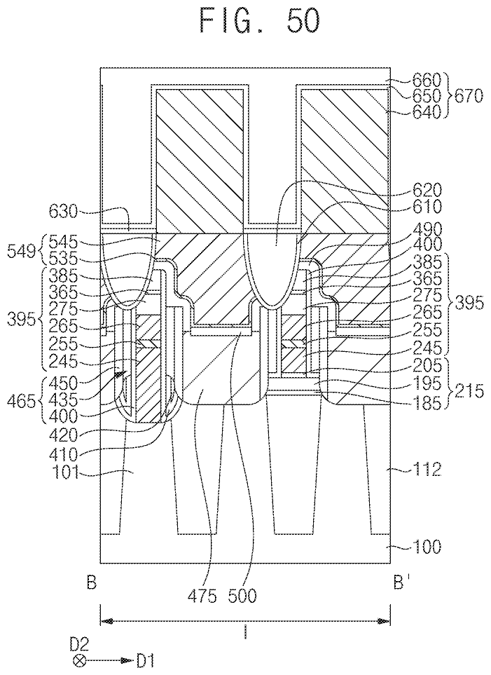

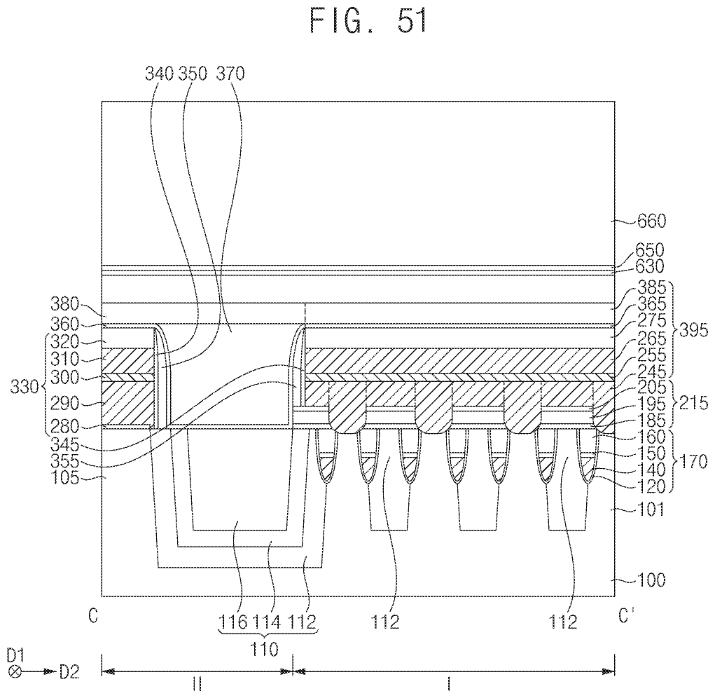

FIGS. 13 to 51 are plan views and cross-sectional views illustrating a method of manufacturing a semiconductor device in accordance with example embodiments. Particularly, FIGS. 13, 16, 19, 25, 30, 37, 41, 45 and 48 are the plan views, FIGS. 14, 17, 20, 23, 26, 29, 31, 34, 38, 42-43, 46 and 49 are cross-sectional views taken along lines A-A′ of corresponding plan views, respectively, FIGS. 21, 24, 27, 32, 35, 39-40, 44, 47 and 50 are cross-sectional views taken along lines B-B′ of corresponding plan views, respectively, FIGS. 15, 18, 22, 28, 33 and 51 are cross-sectional views taken along lines C-C′ of corresponding plan views, respectively, and FIG. 36 is a cross-sectional view taken along line E-E′ of a corresponding plan view.

This method may be an application of the method of forming the pattern illustrated with reference to FIGS. 1 to 12 to a method of forming first and second active patterns of a dynamic random-access memory (DRAM) device, and repeated explanations are omitted herein.

Referring to FIGS. 13 to 15, processes substantially the same as or similar to those illustrated with reference to FIGS. 1 to 12 may be performed to form the first and second active patterns 101 and 105 on the first and second regions I and II, respectively, of the substrate 100.

An isolation structure 110 may be formed to cover sidewalls of the first and second active patterns 101 and 105.

In example embodiments, the isolation structure 110 may include first, second and third isolation patterns 112, 114 and 116 sequentially stacked on an inner wall of the third recess 106. In example embodiments, the first and second isolation patterns 112 and 114 may be formed in the second recess 104 having a width smaller than that of the third recess 106, and the first isolation pattern 112 may be formed in the plurality of first recesses 102 having a width smaller than that of the second recess 104.

Each of the first and third isolation patterns 112 and 116 may include an oxide, e.g., silicon oxide, and the second isolation pattern 114 may include an insulating nitride, e.g., silicon nitride.

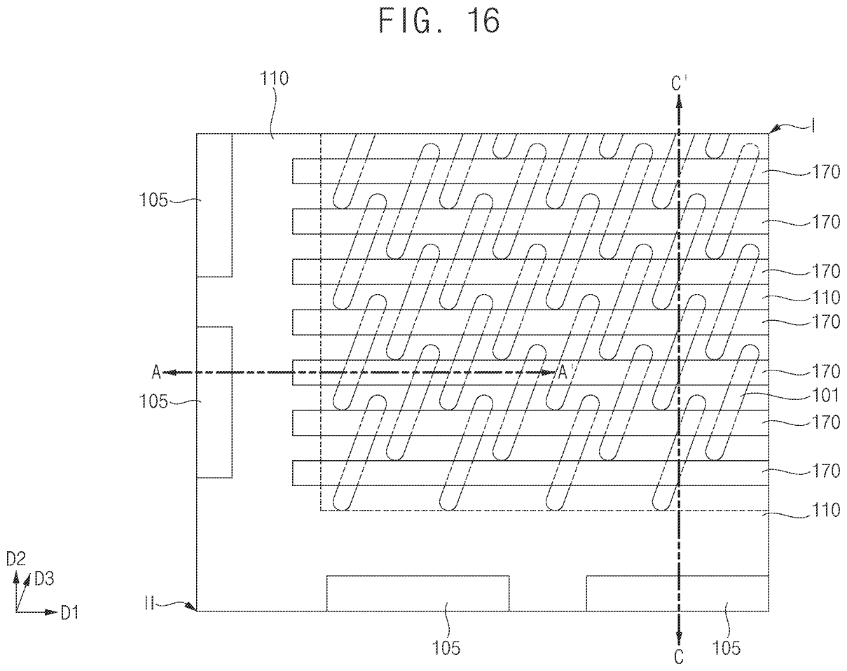

Referring to FIGS. 16 to 18, the first active pattern 101 and the isolation structure 110, which are formed on the first region I and a portion of the second region II adjacent to the first region I, may be etched by an etching process to form a fourth recess 740 extending in the first direction D1.

In example embodiments, the first active pattern 101 including a semiconductor material may be etched less than the isolation structure 110 including an insulating material, during the etching process. Thus, the fourth recess 740 may have a lower surface that is not flat in the first direction D1 but concave upwardly on the upper surface of the first active pattern 101.

A first gate insulation layer and a first conductive layer may be sequentially stacked on an inner wall of the fourth recess 740, upper surfaces of the first and second active patterns 101 and 105, and the isolation structure 110. The first gate insulation layer and the first conductive layer may be planarized until the upper surfaces of the first and second active patterns 101 and 105 and the isolation structure 110 are exposed, and an upper portion of the first conductive layer may be removed by, e.g., an etch back process.

The planarization process may include a chemical mechanical polishing (CMP) process and/or an etch back process.

As the planarization process is performed, a first gate insulation pattern 120 may be formed on the inner wall of the fourth recess 740, and as the etch back process is performed, a first conductive pattern 140 may be formed on the first gate insulation pattern 120 to fill a lower portion of the fourth recess 740.

A second conductive pattern 150 may be formed on the first conductive pattern 140, a first gate mask layer may be formed on the second conductive pattern 150, the first and second active patterns 101 and 105 and the isolation structure 110 to fill the fourth recess 740, and the first gate mask layer may be planarized until the upper surfaces of the first and second active patterns 101 and 105 and the isolation structure 110 are exposed to form a first gate mask 160 in an upper portion of the fourth recess 740. The first conductive pattern 140 and the second conductive pattern 150 may collectively form a gate electrode, and a first barrier pattern may be further formed between the first gate insulation pattern 120 and the first conductive pattern 140.

The first gate insulation pattern 120 may include an oxide, e.g., silicon oxide, the first barrier pattern may include a metal nitride, e.g., titanium nitride, tantalum nitride, etc., the first conductive pattern 140 may include a metal, e.g., tungsten, a metal nitride, e.g., titanium nitride, tantalum nitride, etc., a metal silicide or doped polysilicon, the second conductive pattern 150 may include, e.g., doped polysilicon, and the first gate mask 160 may include a nitride, e.g., silicon nitride.

The first gate insulation pattern 120, the first barrier pattern, the first conductive pattern 140, the second conductive pattern 150 and the first gate mask 160 in the fourth recess 740 may collectively form a first gate structure. In example embodiments, the first gate structure 170 may extend in the first direction D1 on the first region I of the substrate 100 and a portion of the second region II of the substrate 100 adjacent to the first region I in the first direction D1, and a plurality of first gate structures 170 may be spaced apart from each other in the second direction D2. End portions in the first direction D1 of the first gate structures 170 may be aligned with each other in the second direction D2 on the portion of the second region II of the substrate 100.

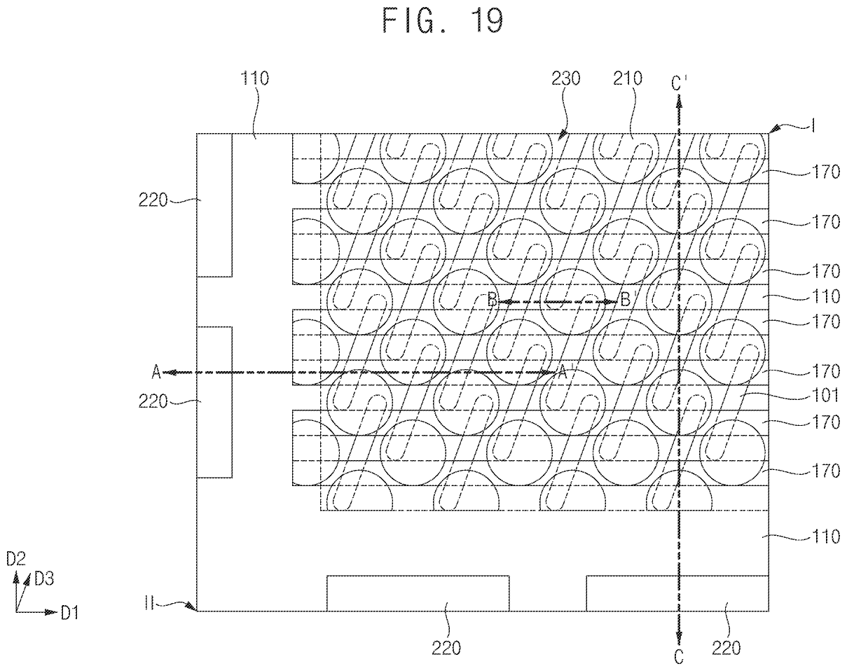

Referring to FIGS. 19 to 22, an insulation layer structure 210 may be formed on the first and second regions I and II of the substrate 100, and a portion of the insulation layer structure 210 on the second region II of the substrate 100, except for the portion of the second region II adjacent to the first region I, may be removed.

For example, a thermal oxidation process may be performed on the second active pattern 105 on the second region II of the substrate 100 to form a second gate insulation layer 220.

The insulation layer structure 210 may be patterned, and the first active pattern 101, the isolation structure 110 and the first gate mask 160 of the first gate structure 170 may be partially etched by an etching process using the patterned insulation layer structure 210 as an etching mask to form a first opening 230. In example embodiments, the insulation layer structure 210 remaining after the etching process may have a shape of, e.g., a circle or an ellipse in a plan view, and a plurality of insulation layer structures 210 may be spaced apart from each other in the first and second directions D1 and D2 on the first region I and the portion of the second region II adjacent to the first region I. Each of the insulation layer structures 210 may overlap end portions, in the third direction D3, of neighboring first active patterns 101, respectively.

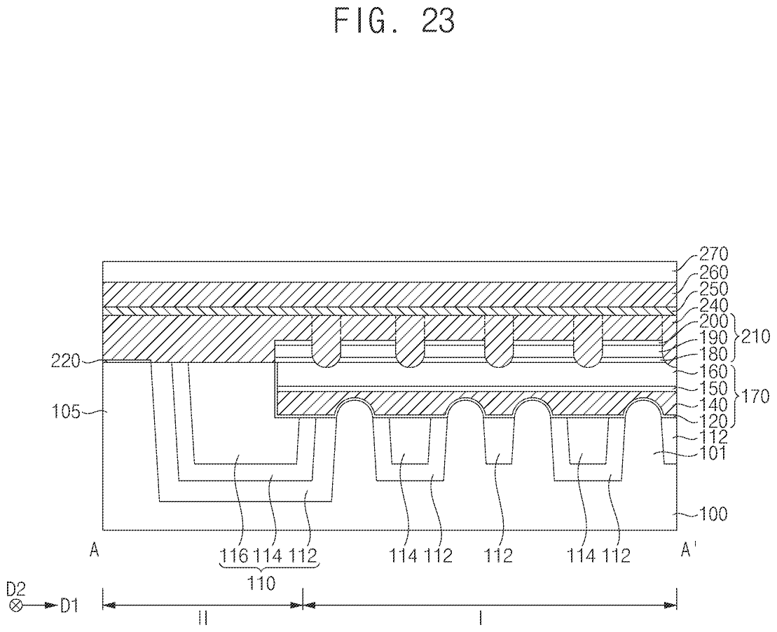

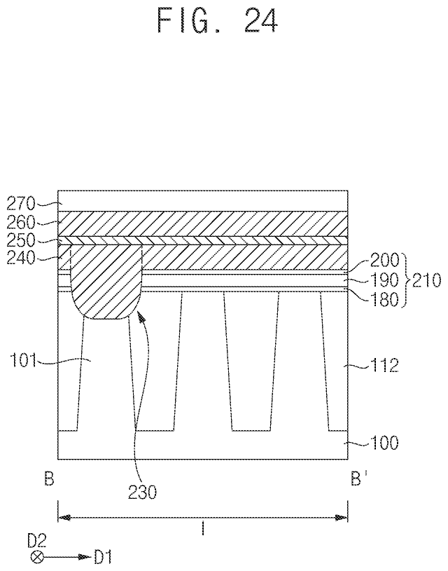

Referring to FIGS. 23 and 24, a third conductive layer 240, a second barrier layer 250, a fourth conductive layer 260 and a sixth mask layer 270 may be sequentially stacked on the insulation layer structure 210. The first active pattern 101, the isolation structure 110 and the first gate structure 170 exposed by the first opening 230 on the first region I of the substrate 100, and the second gate insulation layer 220 and the isolation structure 110 on the second region II of the substrate 100, may collectively form a conductive structure layer. The third conductive layer 240 may fill the first opening 230.

The third conductive layer 240 may include, e.g., doped polysilicon, the second barrier layer 250 may include a metal silicon nitride, e.g., titanium silicon nitride, the fourth conductive layer 260 may include a metal, e.g., tungsten, and the sixth mask layer 270 may include a nitride, e.g., silicon nitride.

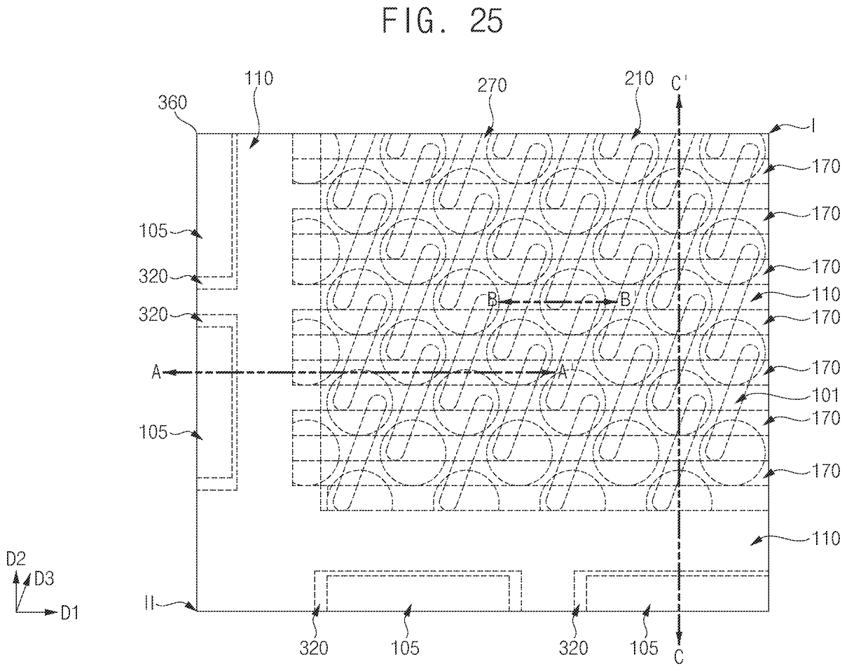

Referring to FIGS. 25 to 28, the conductive structure layer may be patterned to form a second gate structure 330 on the second region II of the substrate 100.

The second gate structure 330 may include a second gate insulation pattern 280, a third conductive pattern 290, a second barrier pattern 300, a fourth conductive pattern 310 and a second gate mask 320 sequentially stacked on the substrate 100 in the vertical direction. The third conductive pattern 290, the second barrier pattern 300 and the fourth conductive pattern 310 sequentially stacked may collectively form a second gate electrode.

The second gate structure 330 may at least partially overlap the second active pattern 105 in the vertical direction on the second region II of the substrate 100.

Additionally, a portion of the conductive structure layer on an edge portion of the first region I of the substrate 100 adjacent to the second region II of the substrate 100 may be removed to partially expose the insulation layer structure 210, and the upper surfaces of the first active pattern 101, the isolation structure 110 and the first gate structure 170 under the first opening 230.

A first spacer structure may be formed on a sidewall of the second gate structure 330, and a second spacer structure may be formed on a sidewall of a portion of the conductive structure layer remaining on the first region I of the substrate 100. The first spacer structure may include first and third gate spacers 340 and 350 sequentially stacked in the horizontal direction from the sidewall of the second gate structure 330, and the second spacer structure may include second and fourth gate spacers 345 and 355 sequentially stacked in the horizontal direction from the sidewall of the conductive structure layer.

The first and second spacers 340 and 345 may be formed by forming a first spacer layer on the substrate 100 having the conductive structure layer and the second gate structure 330 thereon, and anisotropically etching the first spacer layer. The third and fourth spacers 350 and 355 may be formed by forming a second spacer layer on the substrate 100 having the conductive structure layer, the second gate structure 330 and the first and second spacers 340 and 345, and anisotropically etching the second spacer layer.

The first and second spacers 340 and 345 may include a nitride, e.g., silicon nitride, and the third and fourth spacers 350 and 355 may include an oxide, e.g., silicon oxide.

However, example embodiments are not limited thereto, and each of the first and second spacer structures may include a single spacer, or more than two spacers sequentially stacked.

A first etch stop layer 360 may be formed on the substrate 100 having the conductive structure layer, the second gate structure 330, the first and second spacer structures and the isolation structure 110 thereon. The first etch stop layer 360 may include a nitride, e.g., silicon nitride.

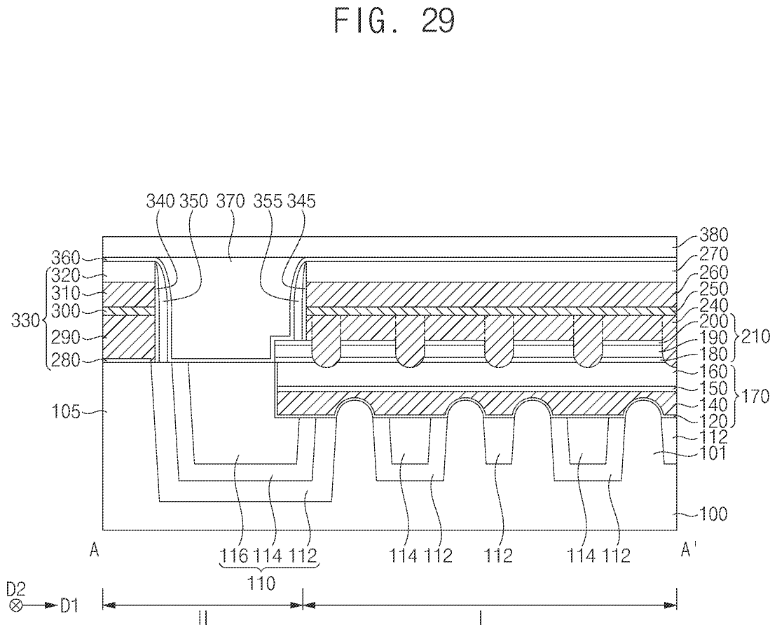

Referring to FIG. 29, a first insulating interlayer 370 may be formed on the first etch stop layer 360, an upper portion of the first insulating interlayer 370 may be planarized until a portion of the first etch stop layer 360 on an upper surface of the second gate structure 330 and an upper surface of the conductive structure layer is exposed, and a capping layer 380 may be formed on the first insulating interlayer 370 and the first etch stop layer 360.

Thus, the first insulating interlayer 370 may fill a space between the first spacer structures on the respective sidewalls of the second gate structures 330, and a space between the first spacer structure on the sidewall of the second gate structure 330 and the second spacer structure on the sidewall of the conductive structure layer.

The first insulating interlayer 370 may include an oxide, e.g., silicon oxide, and the capping layer 380 may include a nitride, e.g., silicon nitride.

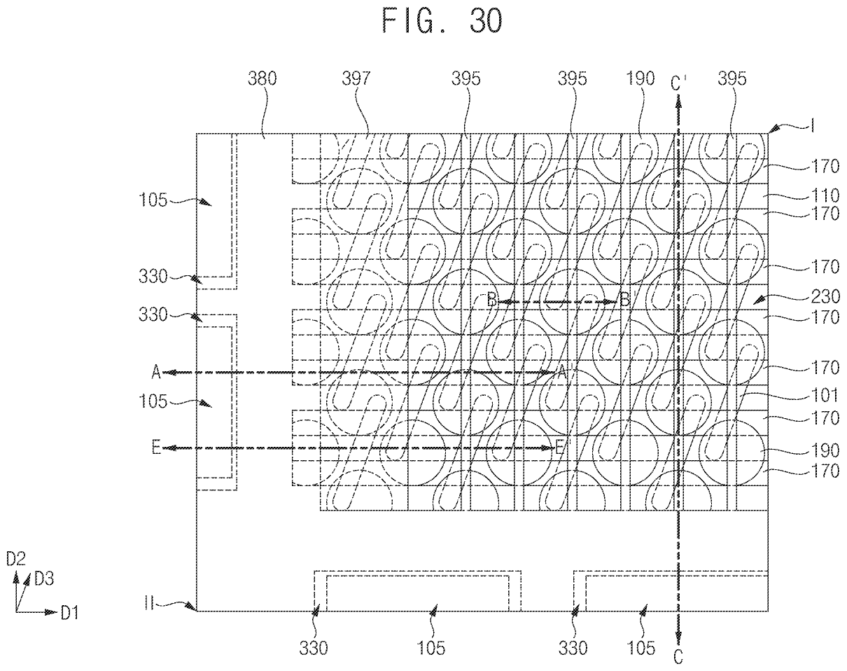

Referring to FIGS. 30 to 33, a portion of the capping layer 380 on the first region I of the substrate 100 may be removed to form a first capping pattern 385, and the first etch stop layer 360, the sixth mask layer 270, the fourth conductive layer 260, the second barrier layer 250 and the third conductive layer 240 may be sequentially etched using the first capping pattern 385 as an etching mask.

In example embodiments, the first capping pattern 385 may extend in the second direction D2, and a plurality of first capping patterns 385 may be spaced apart from each other in the first direction D1 on the first region I of the substrate 100. The capping layer 380 may remain on the second region II of the substrate 100.

By the etching process, a fifth conductive pattern 245, a third barrier pattern 255, a sixth conductive pattern 265, a sixth mask 275, a first etch stop pattern 365 and the first capping pattern 385 may be sequentially stacked on the first opening 230, and a third insulation pattern 205, the fifth conductive pattern 245, the third barrier pattern 255, the sixth conductive pattern 265, the sixth mask 275, the first etch stop pattern 365 and the first capping pattern 385 may be sequentially stacked on a portion of the second insulation layer 190 at an outside of the first opening 230, on the first region I of the substrate 100.

Hereinafter, the fifth conductive pattern 245, the third barrier pattern 255, the sixth conductive pattern 265, the sixth mask 275, the first etch stop pattern 365 and the first capping pattern 385 sequentially stacked may collectively referred to as a bit line structure 395. In example embodiments, the bit line structure 395 may extend in the second direction D2, and a plurality of bit line structures 395 may be spaced apart from each other in the first direction D1 on the first region I of the substrate 100.

A dummy bit line structure 397 extending in the second direction D2 and including a seventh conductive pattern 247, a fourth barrier pattern 257, an eighth conductive pattern 267, a seventh mask 277, a second etch pattern 367 and a second capping pattern 387 sequentially stacked may be formed on the portion of the first region I of the substrate 100 adjacent to the second region II of the substrate 100 in the first direction D1, and the first etch stop layer 360 may remain on the second gate structure 330, the first and second spacer structures, a portion of the insulation layer structure 210, the second active pattern 105 and the isolation structure 110. Additionally, the capping layer 380 may remain on the portion of the first etch stop layer 360 on the upper surface of the second gate structure 330 and the first insulating interlayer 370.

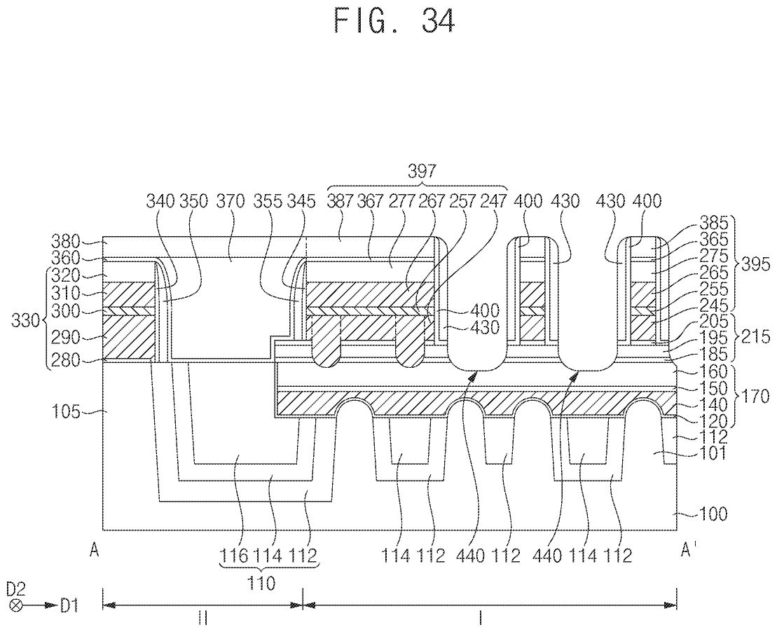

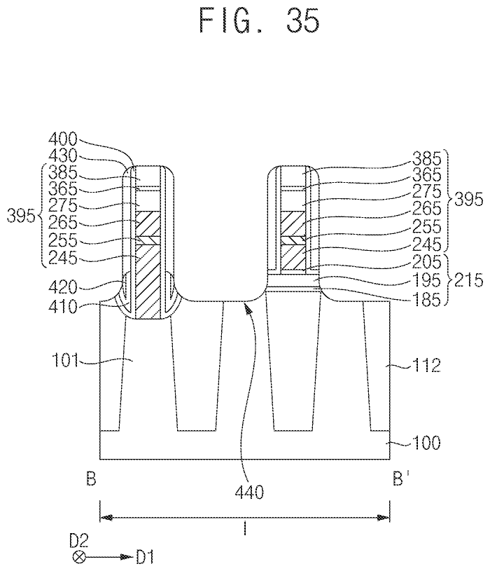

Referring to FIGS. 34 and 35, a fifth spacer layer may be formed on the substrate 100 having the bit line structure 395, the dummy bit line structure 397 and the capping layer 380 thereon, and fourth and fifth insulation layers may be sequentially formed on the fifth spacer layer.

The fifth spacer layer may cover a sidewall of the third insulation pattern 205 under a portion of the bit line structure 395 on the second insulation layer 190, and the fifth insulation layer may fill a remaining portion of the first opening 230.

The fifth spacer layer may include a nitride, e.g., silicon nitride, the fourth insulation layer may include an oxide, e.g., silicon oxide, and the fifth insulation layer may include a nitride, e.g., silicon nitride.

The fourth and fifth insulation layers may be removed by an etching process. In example embodiments, the etching process may include a wet etching process using an etching solution, e.g., H₂PO₃, SCI and HF, and all portions of the fourth and fifth insulation layers except for portions of the fourth and fifth insulation layers in the first opening 230 may be removed. Thus, most portion of a surface of the fifth spacer layer, that is, all portions of the surface of the fifth spacer layer except for a portion of the surface of the fifth spacer layer in the first opening 230 may be exposed, and portions of the fourth and fifth insulation layers remaining in the first opening 230 may form fourth and fifth insulation patterns 410 and 420, respectively.

A sixth spacer layer may be formed on the exposed surface of the fifth spacer layer and the fourth and fifth insulation patterns 410 and 420 in the first opening 230, and may be anisotropically etched to form a sixth spacer 430 on the surface of the fifth spacer layer and the fourth and fifth insulation patterns 410 and 420 to cover a sidewall of the bit line structure 395. The sixth spacer 430 may also be formed on a sidewall of the dummy bit line structure 397. The sixth spacer 430 may include an oxide, e.g., silicon oxide.

For example, a dry etching process may be further performed to form a second opening 440 exposing the upper surface of the first active pattern 101, and the upper surfaces of the isolation structure 110 and the first gate mask 160 may also be exposed by the second opening 440.

By the dry etching process, a portion of the fifth spacer layer on the capping layer 380, the first and second capping patterns 385 and 387 and the second insulation layer 190 may be removed, a fifth spacer 400 may be formed on the sidewall of the bit line structure 395. The fifth spacer 400 may also cover the sidewall of the dummy bit line structure 397.

During the dry etching process, the first and second insulation layers 180 and 190 may also be partially removed, leaving first and second insulation patterns 185 and 195, respectively, under the bit line structure 395. The first to third insulation patterns 185, 195 and 205 under the bit line structure 395 may collectively form an insulation pattern structure 215.

Referring to FIG. 36, a seventh spacer layer may be formed on upper surfaces of the capping layer 380 and the first and second capping patterns 385 and 387, an outer sidewall of the sixth spacer 430, portions of upper surfaces of the fourth and fifth insulation patterns 410 and 420, and the upper surfaces of the first active pattern 101, the isolation structure 110 and the first gate mask 160 exposed by the second opening 440, and may be anisotropically etched to form a seventh spacer 450 covering an outer sidewall of the sixth spacer on the sidewalls of the bit line structure 395 and the dummy bit line structure 397. The seventh spacer 450 may include a nitride, e.g., silicon nitride.

The fifth to seventh spacers 400, 430 and 450 sequentially stacked on the sidewall of the bit line structure 395 in the horizontal direction on the first region I of the substrate 100 may be referred to as a preliminary third spacer structure 460.

A lower contact plug layer may be formed on the first region I of the substrate 100 to fill the second opening 440, and may be planarized until the upper surfaces of the capping layer 380 and the first and second capping patterns 385 and 387 are exposed to form a lower contact plug 475.

The lower contact plug 475 may extend in the second direction D2 between neighboring ones of the bit line structures 395 in the first direction D1 and between the bit line structure 395 and the dummy bit line structure 397, and a plurality of lower contact plugs 475 may be spaced apart from each other in the first direction D1. Each of the lower contact plugs 475 may contact an upper surface of an end portion in the third direction D3 of a corresponding first active pattern 101.

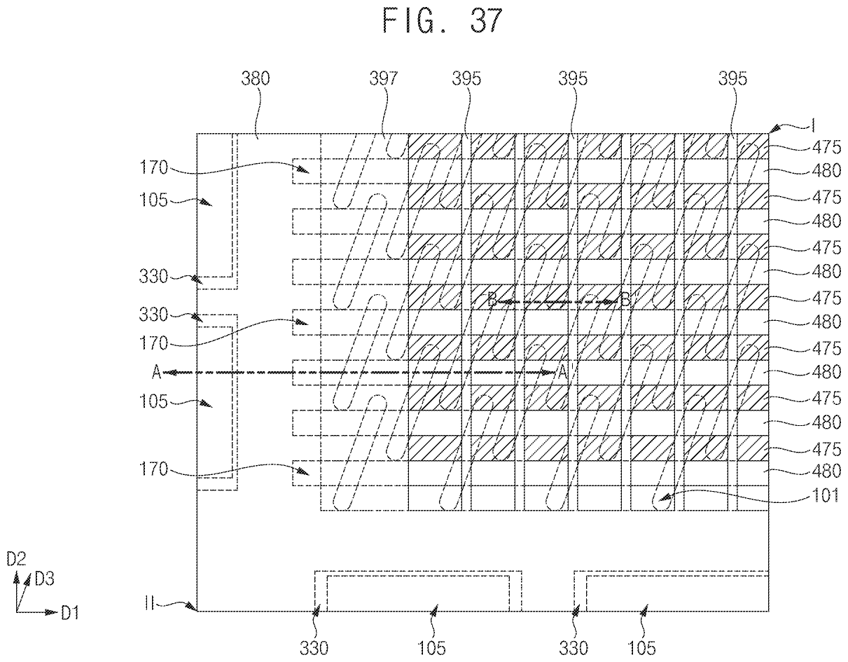

Referring to FIGS. 37 to 39, an etching mask having third openings, each of which may extend in the first direction, spaced apart from each other in the second direction may be formed on the capping layer 380, the bit line structure 395, the dummy bit line structure 397 and the lower contact plug 475, and the lower contact plug 475 may be etched using the etching mask to form a fourth opening 445.

In example embodiments, each of the third openings may overlap the first gate structure 170 in the vertical direction, and thus the upper surface of the first gate mask 160 of the first gate structure 170 may be exposed through the fourth opening 445. As the fourth opening 445 is formed, the lower contact plug 475 extending in the second direction D2 may be divided into a plurality of pieces spaced apart from each other in the second direction D2.

After removing the etching mask, a fence pattern 480 may be formed in the fourth opening 445. In example embodiments, a plurality of fence patterns 480 may be spaced apart from each other in the second direction D2 between neighboring ones of the bit line structures 395 in the first direction D1, and between the bit line structure 395 and the dummy bit line structure 397. The fence pattern 480 may include an insulating nitride, e.g., silicon nitride.

The lower contact plugs 475 and the fence patterns 480 may be alternately arranged in the second direction D2 by forming the lower contact plug 475 extending in the second direction D2 between neighboring ones of the bit line structures 395 in the first direction D1, forming the fourth openings 445 spaced apart from each other in the second direction D2 through the lower contact plug 475, and forming the fence patterns 480 in the fourth openings 445, respectively, however, example embodiments are not limited thereto.

In other example embodiments, the lower contact plugs 475 and the fence patterns 480 may be alternately arranged in the second direction D2 by forming a fence layer extending in the second direction D2 between neighboring ones of the bit line structures 395 in the first direction D1, forming fifth openings spaced apart from each other in the second direction D2 through the fence layer, and forming the lower contact plugs 475 in the fifth openings, respectively.

In still other example embodiments, the lower contact plugs 475 and the fence patterns 480 may be alternately arranged in the second direction D2 by forming a sacrificial layer extending in the second direction D2 between neighboring ones of the bit line structures 395 in the first direction D1 and including an oxide, e.g., silicon oxide, forming the fence patterns 480 spaced apart from each other in the second direction D2 through the sacrificial layer, removing the sacrificial layer to form sixth openings, and forming the lower contact plugs 475 in the sixth openings, respectively.

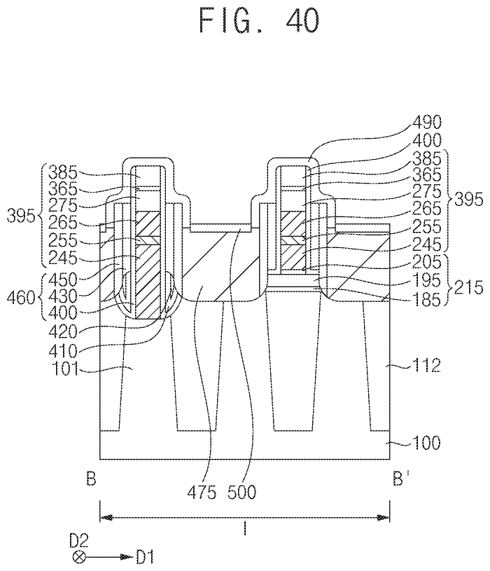

Referring to FIG. 40, an upper portion of the lower contact plug 475 may be removed to expose an upper portion of the preliminary third spacer structure 460 on the sidewalls of the bit line structure 395 and the dummy bit line structure 397, and upper portions of the sixth and seventh spacers 430 and 450 of the exposed preliminary third spacer structure 460 may be removed.

An upper portion of the lower contact plug 475 may be further removed. Thus, an upper surface of the lower contact plug 475 may be lower than uppermost surfaces of the sixth and seventh spacers 430 and 450.

An eighth spacer layer may be formed on the bit line structure 395, the dummy bit line structure 397, the preliminary third spacer structure 460, the fence pattern 480, the capping layer 380 and the lower contact plug 475, and may be anisotropically etched to form an eighth spacer 490 covering an upper portion of the preliminary third spacer structure 460 on each of opposite sidewalls in the first direction D1 of the bit line structure 395. Thus, the upper surface of the lower contact plug 475 may be exposed.

An ohmic contact pattern 500 may be formed on the exposed upper surface of the lower contact plug 475. In example embodiments, the ohmic contact pattern 500 may be formed by forming a first metal layer on the first and second capping patterns 385 and 387, the fence pattern 480, the capping layer 380, the eighth spacer 490 and the lower contact plug 475, and performing a heat treatment process on the first metal layer. An unreacted portion of the first metal layer may be removed. The ohmic contact pattern 500 may include a metal silicide, e.g., cobalt silicide, nickel silicide, titanium silicide, etc.

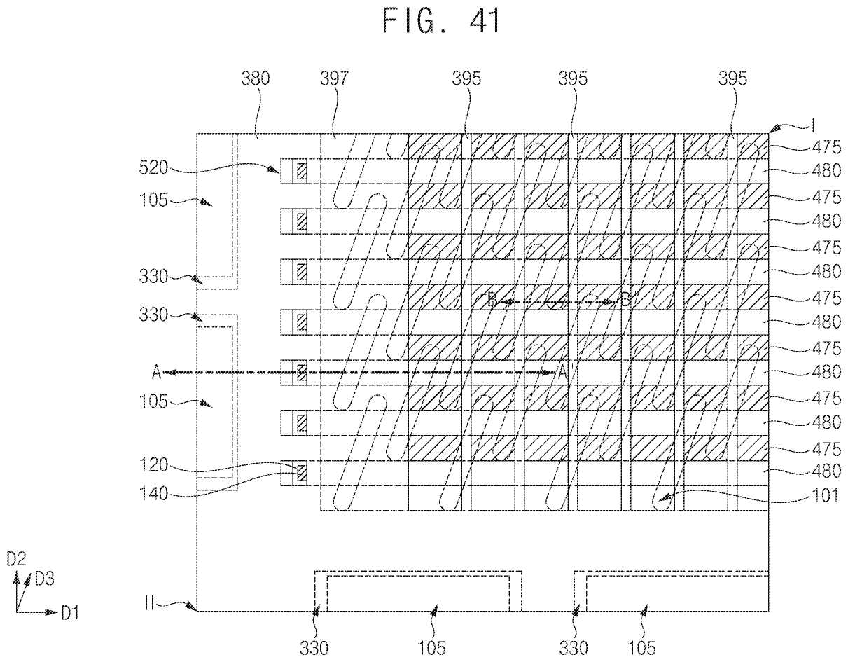

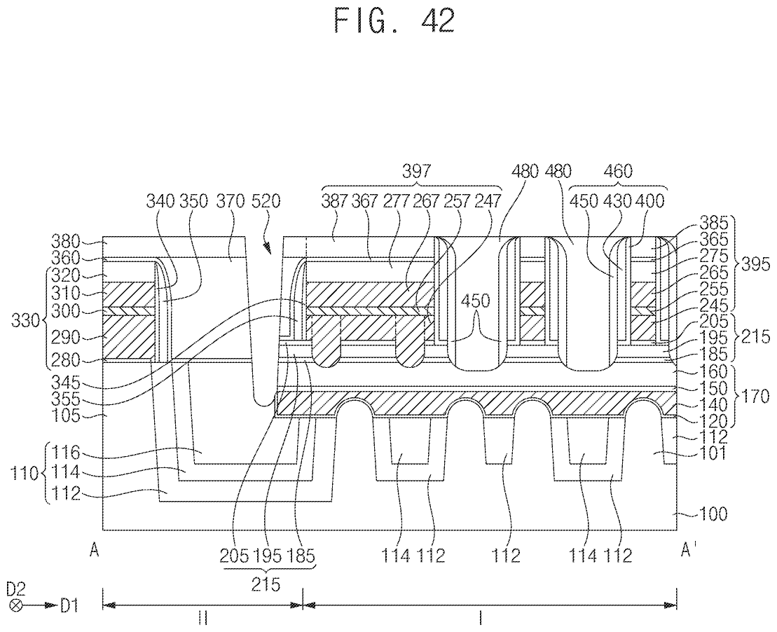

Referring to FIGS. 41 and 42, a seventh opening 520 may be formed through a portion of the capping layer 380 on the portion of the second region II of the substrate 100 adjacent to the first region I of the substrate 100 in the first direction D1, and the first insulating interlayer 370, the first etch stop layer 360, the insulation pattern structure 215, the isolation structure 110, the first gate mask 160 and the second conductive pattern 150 under the portion of the capping layer 380 to expose the first conductive pattern 140. The seventh opening 520 may also expose the first gate insulation pattern 120 on the sidewall of the first conductive pattern 140.

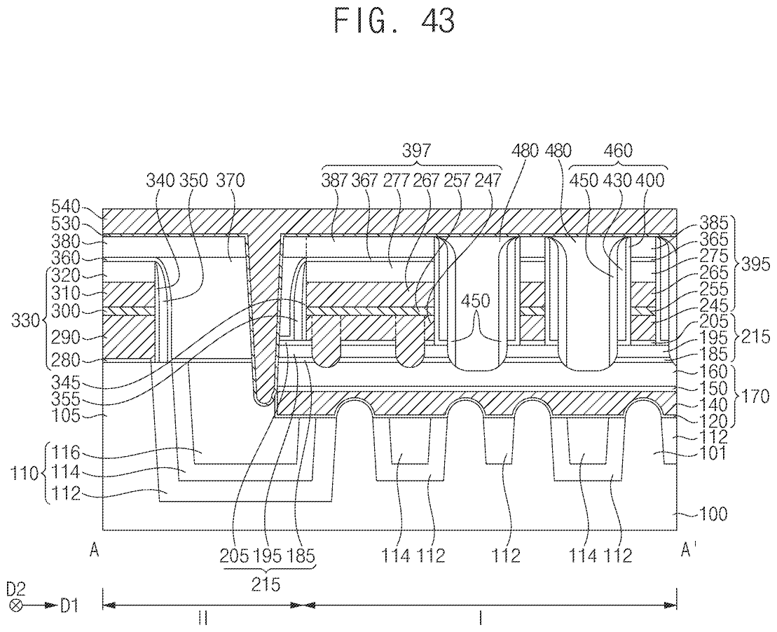

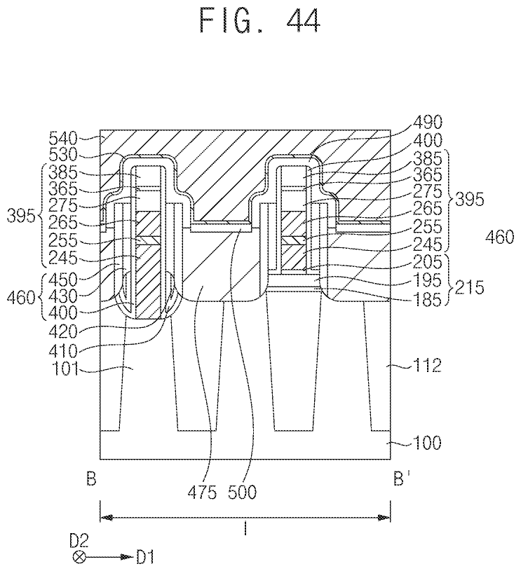

Referring to FIGS. 43 and 44, a fifth barrier layer 530 may be formed on the first and second capping patterns 385 and 387, the fence pattern 480, the eighth spacer 490, the ohmic contact pattern 500 and the lower contact plug 475 on the first region I of the substrate 100, and the capping layer 380, and the isolation structure 110, the first conductive pattern 140 and the first gate insulation pattern 120 exposed by the seventh opening 520 on the second region II of the substrate 100, and a second metal layer 540 may be formed on the fifth barrier layer 530 to fill the space between the bit line structures 395, the space between the bit line structure 395 and the dummy bit line structure 397, and the seventh opening 520.

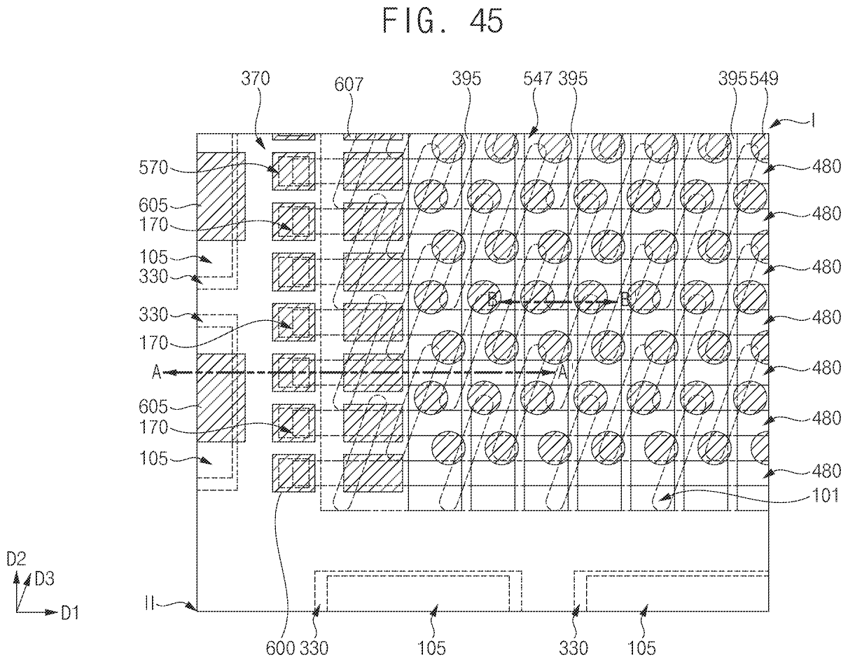

Referring to FIGS. 45 to 47, the second metal layer 540 and the fifth barrier layer 530 may be patterned.

Thus, an upper contact plug 549 may be formed on the first region I of the substrate 100, and a second wiring 605 may be formed on the second region II of the substrate 100. Additionally, a first wiring 600 may be formed on the portion of the second region II of the substrate 100 adjacent to the first region I of the substrate 100, and a third wiring 607 may be formed on the portion of the first region I of the substrate 100 adjacent to the second region II of the substrate 100. An eighth opening 547 may be formed between neighboring ones of the upper contact plug 549 and the first to third wirings 600, 605 and 607.

The eighth opening 547 may be formed by partially removing not only the second metal layer 540 and the fifth barrier layer 530, but also the first and second capping patterns 385 and 387, the fence pattern 480, the capping layer 380, the preliminary third spacer structure 460, the eighth spacer 490, the first etch stop layer 360, the first etch stop pattern 365 and the sixth mask 275, and thus may expose an upper surface of the sixth spacer 430.

As the eighth opening 547 is formed, the second metal layer 540 and the fifth barrier layer 530 may be transformed into a first metal pattern 545 and a fifth barrier pattern 535, respectively, covering a lower surface of the first metal pattern 545 on the first region I of the substrate 100, which may collectively form the upper contact plug 549. In example embodiments, a plurality of upper contact plugs 549 may be spaced apart from each other in the first and second directions D1 and D2 on the first region I of the substrate 100, and may be arranged in a honeycomb pattern. Each of the upper contact plugs 549 may have a shape of, e.g., a circle, an ellipse, or a polygon.

The lower contact plug 475, the ohmic contact pattern 500 and the upper contact plug 549 may collectively form a first contact plug structure on the first region I of the substrate 100.

The first wiring 600 may include a third metal pattern 590 and a seventh barrier pattern 580 covering a lower surface of the third metal pattern 590. A second contact plug 570 including a second metal pattern 560 and a sixth barrier pattern 550 may be formed in the seventh opening 520. The second wiring 605 may include a fourth metal pattern 595 and an eighth barrier pattern 585 covering a lower surface of the fourth metal pattern 595. The third wiring 607 may include a fifth metal pattern 597 and a ninth barrier pattern 587 covering a lower surface of the fifth metal pattern 597.

In example embodiments, the first wiring 600 may overlap the seventh opening 520 in the vertical direction, and a plurality of first wirings 600 may be spaced apart from each other in the second direction D2. The first wiring 600 may be electrically connected to the first conductive pattern 140 through the second contact plug 570, and thus may apply electrical signals to the first gate structure 170. The second wiring 605 may overlap the second gate structure 330 in the vertical direction. The third wiring 607 may overlap the dummy bit line structure 397 in the vertical direction.

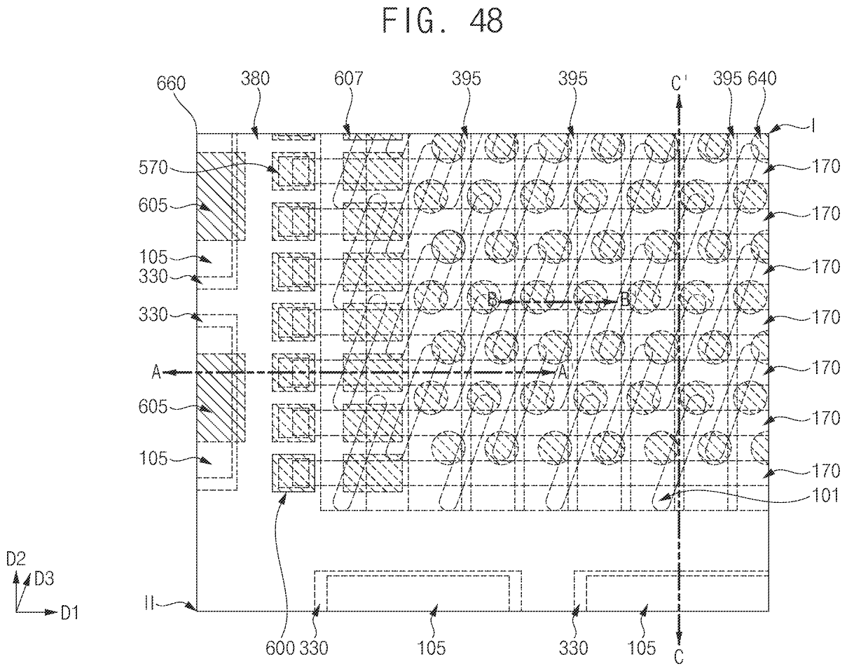

Referring to FIGS. 48 to 51, the sixth spacer 430 may be removed to form an air gap 435 connected to the eighth opening 547. The sixth spacer 430 may be removed by, e.g., a wet etching process.

In example embodiments, not only a portion of the sixth spacer 430 directly exposed by the eighth opening 547 but also other portions of the sixth spacer 430 that are parallel in the horizontal direction thereto may be removed by the wet etching process. That is, not only a portion of the sixth spacer 430 that is exposed by the eighth opening 547 not to be covered by the upper contact plug 549 but also a portion of the sixth spacer 430 covered by the upper contact plug 549 may be removed by the wet etching process.

A second insulating interlayer may be formed to fill the eighth opening 547.

In example embodiments, the second insulating interlayer may include sixth and seventh insulation layers 610 and 620 sequentially stacked. The sixth insulation layer 610 may be formed using an insulating material having poor gap filling characteristics, and thus the air gap 435 under the eighth opening 547 may not be filled. The air gap 435 may also be referred to as an air spacer 435, and the fifth and seventh spacers 400 and 450 and the air spacer 435 may collectively form a third spacer structure 465. The air gap 435 may be a spacer including air. The seventh insulation layer 620 may include an oxide, e.g., silicon oxide or an insulating nitride, e.g., silicon nitride.

A capacitor 670 may be formed to contact an upper surface of the upper contact plug 549.

That is, a second etch stop layer 630 and a mold layer may be formed on the upper contact plug 549, the second insulating interlayer, and the first to third wirings 600, 605 and 607, and may be partially etched to form a ninth opening exposing the upper surface of the upper contact plug 549. The second etch stop layer 630 may include an insulating nitride, e.g., silicon nitride.

A lower electrode layer may be formed on the exposed upper surface of the upper contact plug 549 and the mold layer to fill the ninth opening, and may be planarized until the upper surface of the mold layer is exposed to divide the lower electrode layer. For example, a wet etching process may be performed to remove the mold layer, and a lower electrode 640 having a pillar shape may be formed on the upper surface of the upper contact plug 549. Alternatively, the lower electrode 640 may be formed to have a cylindrical shape in the ninth opening. The lower electrode 640 may include, e.g., a metal, a metal nitride, a metal silicide, doped polysilicon, etc.

A dielectric layer 650 may be formed on the lower electrode 640 and the second etch stop layer 630, and an upper electrode 660 may be formed on the dielectric layer 650 to form the capacitor 670 including the lower electrode 640, the dielectric layer 650 and the upper electrode 660 on the first region I of the substrate 100.

The dielectric layer 650 may include, e.g., a metal oxide, and the upper electrode 660 may include e.g., a metal, a metal nitride, a metal silicide, doped polysilicon, doped silicon-germanium etc.

Contact plugs and upper wirings may be further formed to be electrically connected to the capacitor 670, the bit line structure 395 and the first to third wirings 600, 605 and 607, so that the fabrication of the semiconductor device may be completed.

While aspects of example embodiments have been particularly shown and described, it will be understood that various changes in form and details may be made therein without departing from the spirit and scope of the following claims.

1. A method of forming a pattern, the method comprising:
forming a first recess in a substrate;
forming a first mask layer on the substrate that extends into the first recess;
performing a heat treatment process on the first mask layer;
removing an upper portion of the first mask layer to form a first mask in the first recess, the first mask comprising a lower portion of the first mask layer;
forming a second mask on the substrate and the first mask, the second mask comprising a material having a tolerance with respect to an etching process that is greater than that of the first mask; and
performing an etching process on the substrate using the second mask as an etching mask to form the pattern on the substrate.

2. The method according to claim 1, wherein the first mask layer comprises spin-on-hardmask (SOH), and wherein the second mask comprises amorphous carbon layer (ACL).

3. The method according to claim 1, wherein the heat treatment process comprises a baking process that is performed at a temperature of about 145° C. to about 155° C. for about 60 seconds to about 150 seconds.

4. The method according to claim 1, wherein the removing the upper portion of the first mask layer comprises performing a rinse process using an organic solvent.

5. The method according to claim 1, wherein the forming the second mask comprises:
performing a deposition process on the substrate and the first mask layer to form a second mask layer; and
patterning the second mask layer to form the second mask.

6. The method according to claim 5, wherein an upper surface of the first mask layer is closer to the substrate on a portion of the substrate having the first recess thereon than on a portion of the substrate spaced apart from the first recess, and
wherein an upper surface of the second mask layer has a uniform height with respect to the substrate.

7. The method according to claim 5, further comprising:
sequentially stacking a third mask layer and a fourth mask layer on the second mask layer;
performing a photo process on the fourth mask layer to form a fourth mask;
performing an etching process on the third mask layer using the fourth mask as an etching mask to form a third mask; and
performing an etching process on the second mask layer using the third mask as an etching mask to form the second mask.

8. The method according to claim 7, wherein the third mask layer comprises silicon nitride, and
wherein the fourth mask layer comprises a photoresist layer.

9. The method according to claim 1, wherein the forming the first recess on the substrate comprises:
forming a third mask on the substrate; and
performing an etching process using the third mask as an etching mask to remove an upper portion of the substrate,
wherein the first mask layer is formed on the third mask, and
wherein an upper surface of the first mask is substantially coplanar with an upper surface of the third mask.

10. The method according to claim 1, wherein the substrate comprises a first region and a second region surrounding the first region,
wherein the first recess extends into the first region of the substrate, and
wherein the performing the etching process on the substrate comprises forming a second recess that extends into the second region of the substrate.

11. The method according to claim 10, wherein a width and a depth of the second recess are greater than a width and a depth, respectively, of the first recess.

12. The method according to claim 10, wherein the forming the first recess comprises forming a plurality of first recesses spaced apart from each other and extending into the substrate, the first recess being one of the plurality of first recesses, and
wherein the performing the etching process on the substrate comprises forming the second recess between neighboring ones of the plurality of first recesses on the first region of the substrate, the second recess having a width and a depth greater than a width and a depth, respectively, of each of the plurality of first recesses.

13. A method of forming a pattern, the method comprising:
forming a recess in a substrate;
forming a first mask layer on the substrate that extends into the recess, wherein an upper surface of the first mask layer is closer to the substrate on a portion of the substrate having the recess thereon than on a portion of the substrate spaced apart from the recess;
removing an upper portion of the first mask layer to form a first mask in the recess, the first mask comprising a portion of the first mask layer;
forming a second mask on the substrate and the first mask, the second mask comprising a material different from that of the first mask, and an upper surface of the second mask having a uniform height with respect to the substrate; and
performing an etching process on the substrate using the second mask as an etching mask to form the pattern on the substrate.

14. The method according to claim 13, wherein the first mask layer comprises spin-on-hardmask (SOH), and
wherein the second mask comprises amorphous carbon layer (ACL).

15. The method according to claim 13, wherein the removing the upper portion of the first mask layer comprises performing a rinse process using an organic solvent.

16. The method according to claim 15, further comprising, prior to removing the upper portion of the first mask layer, performing a heat treatment process on the first mask layer.

17. A method of manufacturing a semiconductor device, the method comprising:
forming a first recess in a first region of a substrate, the substrate comprising the first region and a second region;
forming a first mask layer on the substrate that extends into the first recess;
performing a heat treatment process on the first mask layer;
removing an upper portion of the first mask layer to form a first mask in the first recess, the first mask comprising a portion of the first mask layer;
forming a second mask on the substrate and the first mask, the second mask comprising a material having a tolerance with respect to an etching process that is greater than that of the first mask;
performing an etching process using the second mask as an etching mask on the substrate and the first mask to form second and third recesses in the first and second regions, respectively, of the substrate, a first active pattern being defined by the first and second recesses on the first region of the substrate and a second active pattern being defined by the third recess on the second region of the substrate;
forming an isolation structure in the first to third recesses;
forming a gate structure through the first active pattern and the isolation structure in the first region of the substrate;
forming a bit line structure on a portion of the first active pattern and a portion of the isolation structure;
forming a contact plug structure on the portion of the first active pattern; and
forming a capacitor on the contact plug structure.

18. The method according to claim 17, wherein the first mask layer comprises spin-on-hardmask (SOH), and
wherein the second mask comprises amorphous carbon layer (ACL).

19. The method according to claim 17, wherein forming the second mask comprises:
performing a deposition process on the substrate and the first mask layer to form a second mask layer; and
patterning the second mask layer to form the second mask,
wherein an upper surface of the first mask layer on the first region of the substrate is closer to the substrate than on the second region of the substrate spaced apart from the first recess, and
wherein an upper surface of the second mask layer has a uniform height with respect to the substrate.

20. The method according to claim 17, wherein the forming the first recess comprises forming a plurality of first recesses spaced apart from each other and extending into the substrate, the first recess being one of the plurality of first recesses, and
wherein the performing the etching process using the second mask comprises forming the second recess between neighboring ones of the plurality of first recesses, the second recess having a width and a depth greater than a width and a depth, respectively, of each of the plurality of first recesses.

21. (canceled)
